(19) United States
(12) Patent Application Publication
(10) Pub. No.: US 2025/0386529 A1
(43) Pub. Date: Dec. 18, 2025

(54) SEMICONDUCTOR DEVICE AND METHODS OF FORMING SAME

(71) Applicant: Taiwan Semiconductor Manufacturing Co., Ltd., Hsinchu (TW)

(72) Inventors: Ching-Lin Hsieh, Hsinchu (TW); Yen-Chun Huang, Taipei City (TW); Ching-Hung Chen, Houlong Township (TW); Mu-Chieh Chang, Zhubei City (TW); Wei Liu, Kaohsiung City (TW); Yu-Cheng Shiau, Hsinchu (TW); Yi-Syuan Kuo, Hsinchu (TW); Wei-Fang Chen, Hsinchu (TW)

(21) Appl. No.: 18/961,698

(22) Filed: Nov. 27, 2024

Related U.S. Application Data
(60) Provisional application No. 63/660,671, filed on Jun. 17, 2024.

(51) Int. Cl. H01L 29/66

(52) U.S. Cl. CPC H10D 30/014; H10D 64/018

(57) ABSTRACT

A method includes forming a first semiconductor layer and a second semiconductor layer over a substrate; performing a first etch process on the first semiconductor layer and the second semiconductor layer to form a first fin; forming a gate structure across the first fin; performing a second etch process to form a first recess and a second recess in the first fin; removing the first semiconductor layer; depositing a first material layer along exposed surfaces of the second semiconductor layer and the substrate; depositing a second material layer over the first material layer; etching the first material layer and the second material layer to form a third recess, a first etch rate of the first material layer being different than a second etch rate of the second material layer; forming an inner spacer in the third recess; and forming a source/drain region in the first recess.

### PRIORITY CLAIM AND CROSS-REFERENCE

This application claims the benefit of U.S. Provisional Application No. 63/660,671, filed on Jun. 17, 2024, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5A-5B, 6A-6B, 7A-7C, 8A-8B, 9A-9B, 10A-10B, 11A-11E, 12A-12H, 13A-13D, 14A-14B, 15A-15B, 16A-16F, 17A-17F, 18A-18C, 19A-19C, and 20A-20C illustrate varying views of intermediary steps of manufacturing a nano-FET transistor, in accordance with some embodiments.

FIGS. 21A-21B, 22A-22B, 23A-23B, 24A-24E, 25A-25B, and 26A-26G illustrate varying views of intermediary steps of manufacturing a nano-FET transistor, in accordance with some embodiments.

FIGS. 27A-27D, 28A-28D, 29A-29D, 30A-30D, 31A-31D, 32A-32D, and 33A-33D illustrate varying views of intermediary steps of manufacturing a nano-FET transistor, in accordance with some embodiments.

FIGS. 34A-34C, 35A-35C, 36A-36C, 37A-37C, and 38A-38C illustrate varying views of intermediary steps of manufacturing a nano-FET transistor, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments are described below in a particular context, a die comprising nano-FETs. Various embodiments may be applied, however, to dies comprising other types of transistors (e.g., stacking transistors, or the like) in lieu of or in combination with the nano-FETs.

In various embodiments, a nano-FET is fabricated by forming a stack of alternating types of epitaxy layers (e.g., first semiconductor layers and second semiconductor layers) over a semiconductor substrate and patterning the stack into nanostructures. The first semiconductor layers will be removed, and the second semiconductor layers will become channel regions for the nano-FET (e.g., nanostructure channels). In some embodiments, the first semiconductor layers are removed and replaced with a sacrificial material, which will be subsequently replaced with a gate structure. The sacrificial material may comprise a plurality of layers which have distinct and particular properties such as varying etch rates. The sacrificial material is recessed to form notches extending inward from sidewalls of the nanostructure channels, and inner spacers are formed in the notches. The particular properties (e.g., etch rates) of the layers of the sacrificial material allow for the notches to be etched into desired profiles. The desired profiles allow for improved processes for forming the inner spacers to have desired shapes and dimensions and reducing risk of damage to the nanostructure channels. Source/drain regions are then epitaxially grown over the sidewalls of the nanostructure channels, and the sacrificial material is then replaced with a gate structure to form the nano-FET. As a result of the embodiments described herein, the nano-FET may be fabricated at a greater yield and function with improved reliability and performance.

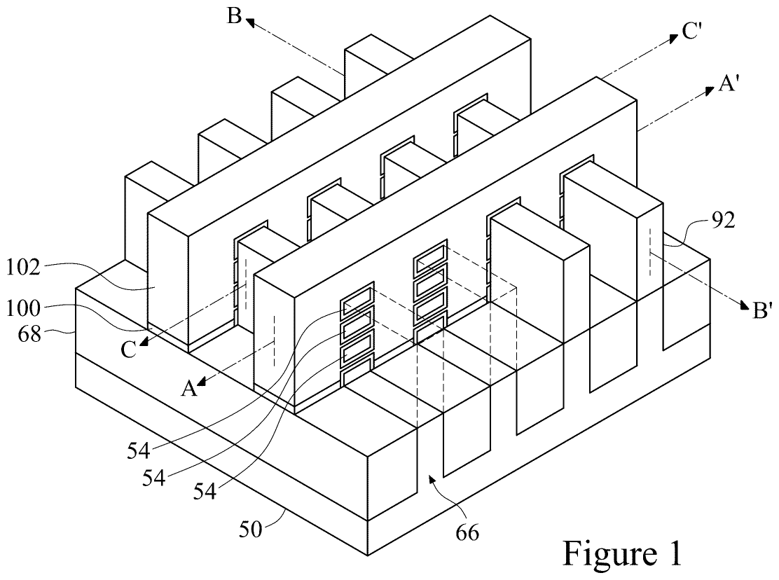

FIG. 1 illustrates an example of nano-FETs (e.g., nanowire FETs, nanosheet FETs (Nano-FETs), or the like) in a three-dimensional view, in accordance with some embodiments. Certain features are simplified and/or omitted in FIG. 1 for ease of illustration. The nano-FETs comprise second nanostructures 54 (e.g., nanosheets, nanowire, or the like) over fins 66 on a substrate 50 (e.g., a semiconductor substrate), wherein the second nanostructures 54 act as channel regions for the nano-FETs. The second nanostructures 54 may include p-type nanostructures, n-type nanostructures, or a combination thereof. STI regions 68 (also referred to as STI structures or STI regions) are disposed between adjacent fins 66, which may protrude above and from between neighboring STI regions 68. Although the STI regions 68 is described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring STI regions 68.

Gate dielectric layers 100 are over top surfaces of the fins 66 and along top surfaces, sidewalls, and bottom surfaces of the second nanostructures 54. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

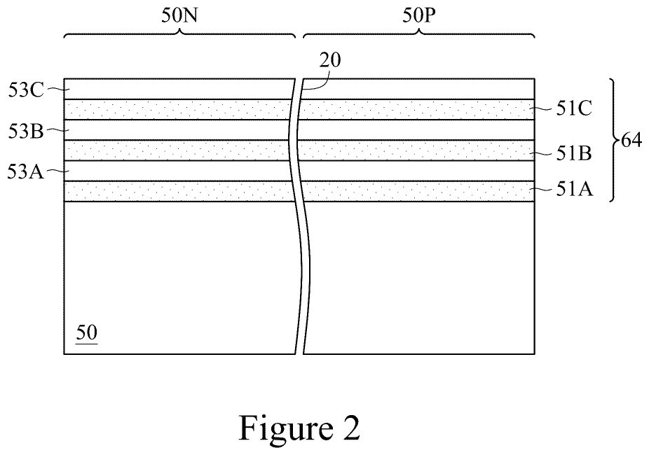

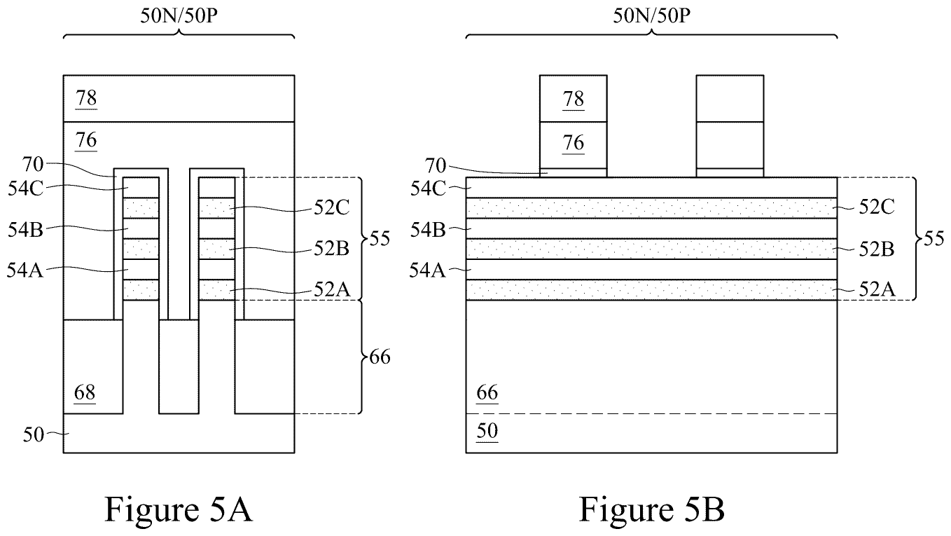

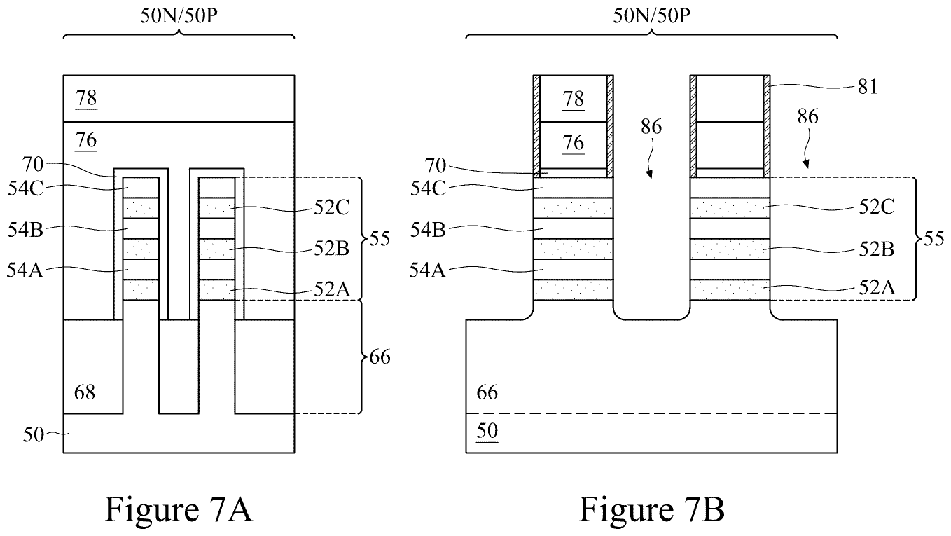

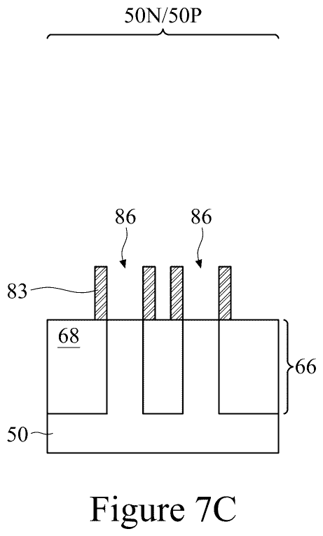

FIGS. 2 through 38C are cross-sectional views of intermediate stages in the manufacturing of nano-FETs, in accordance with some embodiments. FIGS. 2-4, 5A, 6A, 7A, 8A, 9A, 10A, 11A, 12A, 13A, 14A, 15A, 16A, 17A, 18A, 19A, 20A, 21A, 22A, 23A, 24A, 25A, 26A, 27A, 28A, 29A, 30A, 31A, 32A, 33A, 34A, 35A, 36A, 37A, and 38A illustrate reference cross-section A-A′ illustrated in FIG. 1. FIGS. 5B, 6B, 7B, 8B, 9B-9D, 10B-10D, 11B-11E, 12B-12G, 13B, 14B, 15B, 16B-F, 17B-17F, 18B, 19B, 20B, 21B, 22B, 23B, 24B-E, 25B, 26B-G, 27B-D, 28B-D, 29B-D, 30B-D, 31B-D, 32B-D, 33B-D, 34B, 35B, 36B, 37B, and 38B illustrate reference cross-section B-B′ illustrated in FIG. 1. FIGS. 7C, 13C, 13D, 18C, 19C, and 20C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided. Subsequent figures describe processing steps that may be performed in either the n-type regions 50N or the p-type regions 50P unless otherwise noted.

Further in FIG. 2, a multi-layer stack 64 is formed over the substrate 50. The multi-layer stack 64 includes alternating epitaxy layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of nano-FETs in both the n-type region 50N and the p-type region 50P. Nevertheless, in some embodiments, the second semiconductor layers 53 may be removed and the first semiconductor layers 51 may be patterned to form channel regions of nano-FETs in both the n-type region 50N and the p-type region 50P. For example, the channel regions in both the n-type region 50N and the p-type region 50P may have a same material composition (e.g., silicon, or the another semiconductor material) and be formed simultaneously.

In other embodiments, the first semiconductor layers 51 may be removed and the second semiconductor layers 53 may be patterned to form channel regions of nano-FETs in the p-type region 50P, and the second semiconductor layers 53 may be removed and the first semiconductor layers 51 may be patterned to form channel regions of nano-FETs in the n-type region 50N. In still other embodiments, the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In such embodiments, the channel regions of the n-type region 50N may have a different material composition than the channel regions of the p-type region 50P. The first semiconductor layers 51 and the second semiconductor layers 53 may be selectively removed from each of the n-type region 50N and p-type region 50P through additional masking and etching steps. For example, the channel regions of the n-type region 50N may be silicon channel regions while the channel regions of the p-type region 50P may be silicon germanium channel regions. As such, in some embodiments, the first semiconductor layers 51 may comprise crystalline silicon germanium while the second semiconductor layers 53 may comprise crystalline silicon, and vice versa.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

In various embodiments, the first semiconductor layers 51 may be formed of a first semiconductor material, such as silicon germanium, or the like, and the second semiconductor layers 53 may be formed of a second semiconductor material, such as silicon, silicon carbon, or the like. The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions of the nano-FETs.

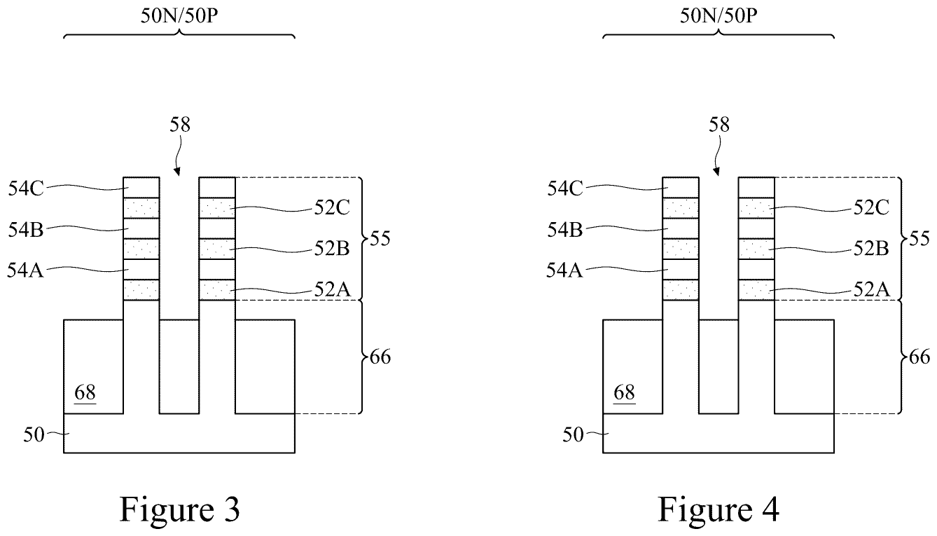

Referring R now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches 58 in the multi-layer stack 64 and the substrate 50. The etching may be any acceptable etch process, such as a reactive ion etch (RIE), neutral beam etch (NBE), the like, or a combination thereof. The etching may be anisotropic. During the etching process, a hard mask may be used to define a pattern of the fins 66 and the nanostructures 55. The hard mask may comprise any suitable insulating material, such as an oxide, a nitride, and oxynitride, and oxycarbonitride, or the like. In some embodiments (not separately illustrated), the hard mask may be a multi-layer structure. The hard mask may be formed over the nanostructures 55 using an acceptable process(es) such as thermal oxidation, physical vapor deposition (PVD), CVD, ALD, combinations thereof, or the like.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66 and the nanostructures 55.

Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as the nanostructures 55.

FIG. 3 illustrates the fins 66 having substantially equal widths for illustrative purposes. In some embodiments, widths of the fins 66 in the n-type region 50N may be greater or thinner than the fins 66 in the p-type region 50P. Further, while FIG. 3 illustrates each of the fins 66 and the nanostructures 55 as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66 to fill the trenches 58. The insulation material may be an oxide, such as silicon oxide, a nitride, the like, or a combination thereof, and may be formed by high-density plasma CVD (e.g., HDP-CVD), flowable CVD (e.g., FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

Further in FIG. 4, appropriate wells (not separately illustrated) may be formed in the fins 66 and/or the nanostructures 55. In embodiments with different well types, different implant steps for the n-type region 50N and the p-type region 50P may be achieved using a photoresist or other masks (not separately illustrated). For example, a photoresist may be formed over the fins 66 and the nanostructures 55 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66 and the nanostructures 55 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

In FIGS. 5A and 5B, dummy gates are formed over and along sidewalls of the nanostructures 55 and the fin 66. To form the dummy gates, first, a dummy dielectric layer is formed on the fins 66 and/or the nanostructures 55. The dummy dielectric layer may be, for example, silicon oxide, silicon nitride, a combination thereof, or the like, and may be deposited or thermally grown according to acceptable techniques. A dummy gate layer is formed over the dummy dielectric layer, and a mask layer is formed over the dummy gate layer. The dummy gate layer may be deposited over the dummy dielectric layer and then planarized, such as by a CMP. The mask layer may be deposited over the dummy gate layer. The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be made of other materials that have a high etching selectivity from the etching of isolation regions. The mask layer may include, for example, silicon nitride, silicon oxynitride, or the like.

Subsequently, the mask layer may be patterned using acceptable photolithography and etching techniques to form masks 78. The pattern of the masks 78 then may be transferred to the dummy gate layer and to the dummy dielectric layer to form dummy gates 76 and dummy gate dielectrics 70, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66. It is noted that the dummy gate dielectrics 70 is shown covering only the fins 66 and the nanostructures 55 for illustrative purposes only. In some embodiments, the dummy gate dielectrics 70 may be deposited such that the dummy gate dielectrics 70 cover the STI regions 68, such that the dummy gate dielectrics 70 extend between the dummy gates 76 and the STI regions 68.

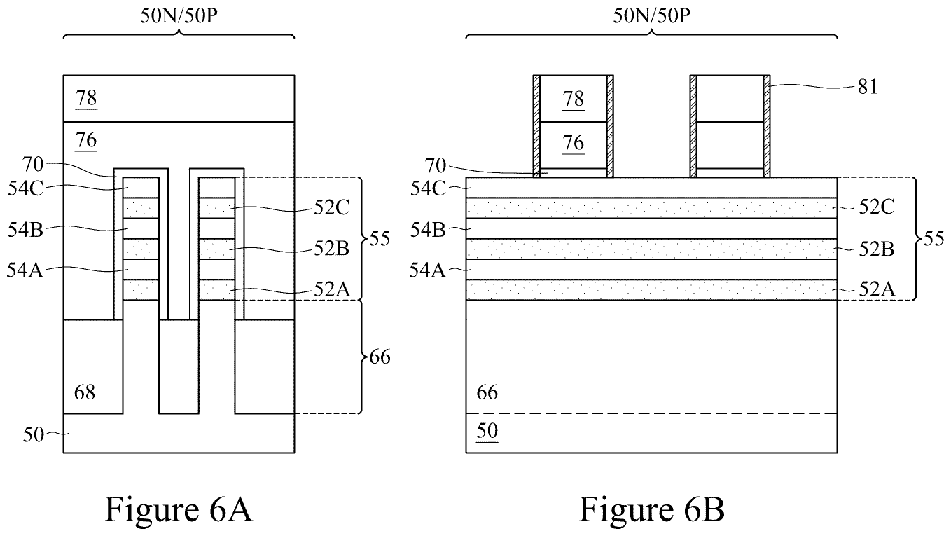

In FIGS. 6A and 6B, gate spacers 81 are formed over the nanostructures 55 and the STI regions 68, on exposed sidewalls of the masks 78 (if present), the dummy gates 76, and the dummy gate dielectrics 70. The gate spacers 81 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 76 (thus forming the gate spacers 81). As subsequently described in greater detail, the dielectric material(s), when etched, may also have portions left on the sidewalls of the semiconductor fins 66 and/or the nanostructures 55 (thus forming fin spacers 83, see FIG. 7C). After etching, the fin spacers 83 and/or the gate spacers 81 can have straight sidewalls (as illustrated) or can have curved sidewalls (not separately illustrated).

Further, implants for lightly doped source/drain (LDD) regions (not separately illustrated) may be performed. The LDD implants may be performed before the gate spacers 81 are formed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the semiconductor fins 66 and the nanostructures 55 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the semiconductor fins 66 and the nanostructures 55 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from 10¹⁵ atoms/cm³ to 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

In FIGS. 7A-7C, first recesses 86 are formed in the fins 66, the nanostructures 55, and the substrate 50, in accordance with some embodiments. Epitaxial source/drain regions will be subsequently formed in the first recesses 86 (e.g., source/drain recesses). The first recesses 86 may extend through the first nanostructures 52 and the second nanostructures 54, and into the substrate 50. As illustrated in FIG. 7C, top surfaces of the STI regions 68 may be level with bottom surfaces of the first recesses 86. In other embodiments, the fins 66 may be etched such that bottom surfaces of the first recesses 86 are disposed above or below the top surfaces of the STI regions 68. The first recesses 86 may be formed by etching the fins 66, the nanostructures 55, and the substrate 50 using anisotropic etching processes, such as RIE, NBE, or the like. The gate spacers 81, the fin spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

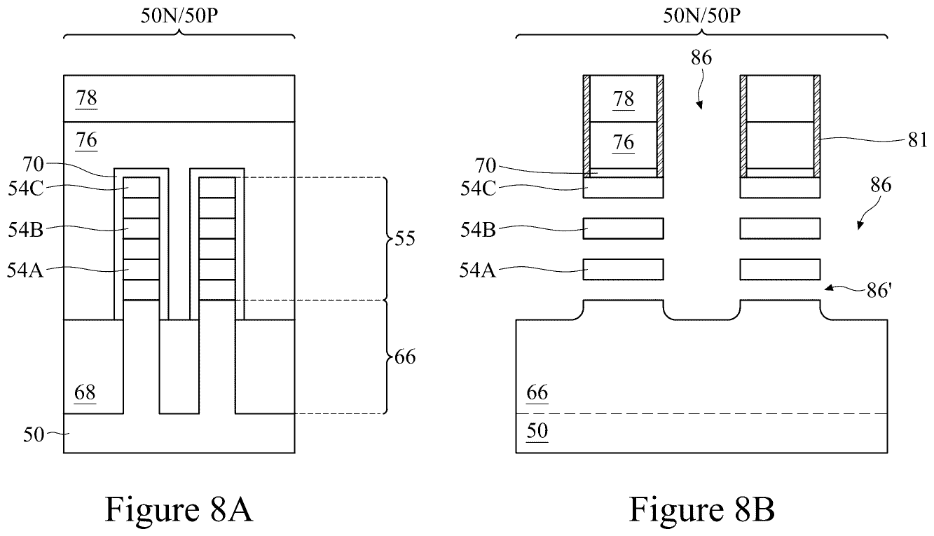

FIGS. 8A-10B illustrate replacing the first nanostructures 52 with a sacrificial material 72 (also referred to as disposable oxide interposers (DOI)). As such, the sacrificial material 72 may also be considered nanostructures (e.g., dielectric nanostructures). As discussed in greater detail below, the sacrificial material 72 may comprise a plurality of layers.

In FIGS. 8A and 8B, replacing the first nanostructures 52 may include etching away the first nanostructures 52 using a suitable etch process, such as an isotropic etch process, that is performed through the first recesses 86. The etch process may be selective to the material of the first nanostructures 52 and remove the first nanostructures 52 without significantly removing the second nanostructures 54 or the semiconductor fins 66. As a result, the first recesses 86 are extended to form spaces or gaps 86′ between the second nanostructures 54. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to remove the first nanostructures 52.

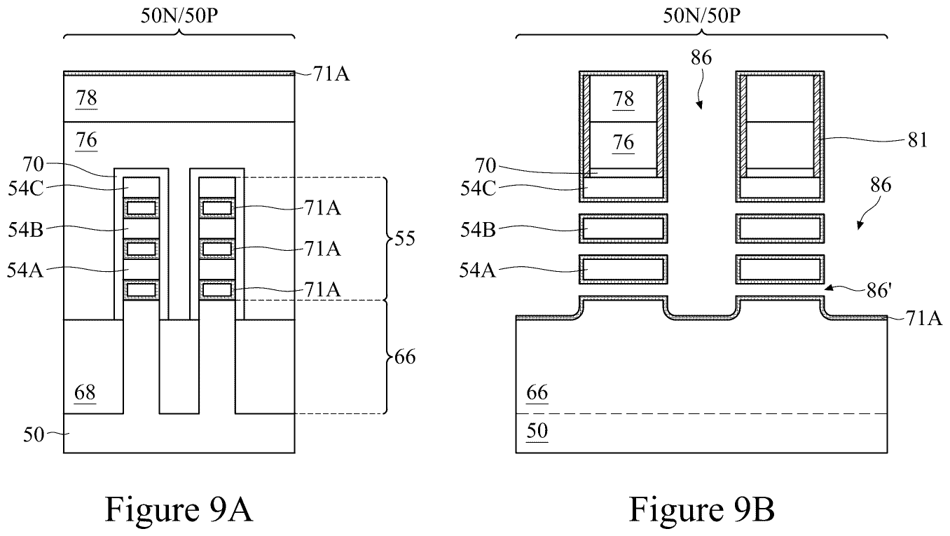

In FIGS. 9A and 9B, a first material layer 71A is deposited in the recesses 86 and gaps 86′ where the first nanostructures 52 were removed. The first material layer 71A may be deposited by a conformal deposition process, such as ALD, CVD (e.g., FCVD), or the like. The first material layer 71A may comprise an insulating material such as silicon oxide (e.g., SiOₓ such as SiO₂), silicon nitride, silicon oxycarbide, silicon oxycarbonitride, or the like that can be selectively etched from the second nanostructures 54. In various embodiments, the first material layer 71A is free of germanium. The first material layer 71A may have a thickness ranging from 1 nm to 2 nm. The thickness being about 1 nm or greater ensures full coverage over the second nanostructures 54 within the gaps 86′ of the recesses 86. The thickness being about 2 nm or less ensures that openings to the gaps 86′ of the recesses 86 are not blocked or pinched.

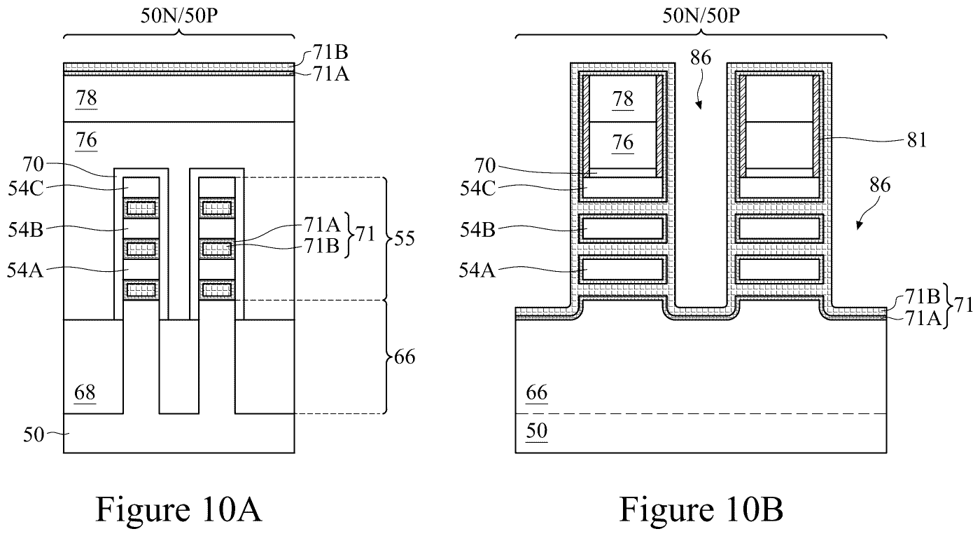

In FIGS. 10A and 10B, a second material layer 71B is deposited over the first material layer 71A in the recesses 86 (and the gaps 86′ between the second nanostructures 54 where the first nanostructures 52 were removed). In accordance with some embodiments, the second material layer 71B fills a remainder of the gaps 86′ of the recesses 86 between the second nanostructures 54. As illustrated, the resulting combined material layer 71 (e.g., the first material layer 71A and the second material layer 71B, collectively) comprises tri-layer portions between the second nanostructures 54. The second material layer 71B may be deposited by a conformal or gap-fill process, such as ALD, CVD (e.g., FCVD), or the like. The second material layer 71B may comprise an insulating material such as silicon oxide (e.g., SiOₓ such as SiO₂), silicon germanium, silicon nitride, silicon oxycarbide, silicon oxycarbonitride, or the like that can be selectively etched from the second nanostructures 54.

In accordance with various embodiments, the first material layer 71A and the second material layer 71B have different compositions and/or structures in order for the resulting layers 71A/71B, which may therefore have different etch selectivities from one another. In some such embodiments, these layers 71A/71B may be formed of the same material (e.g., silicon oxide or another listed above) using different processes. For example, the first material layer 71A may be formed by ALD, and the second material layer 71B may be formed by FCVD. In other such embodiments, these layers 71A/71B may be formed of different materials among those listed using the same process (e.g., ALD or FCVD). In yet other such embodiments, these layers 71A/71B may be formed of different materials among those listed and using different processes. In particular, any suitable combinations of materials and processes may be utilized to result in particular properties (e.g., densities, compositions, chemical bonding structures, or crystal phases) to tune the layers 71A/71B to have desired etch rates.

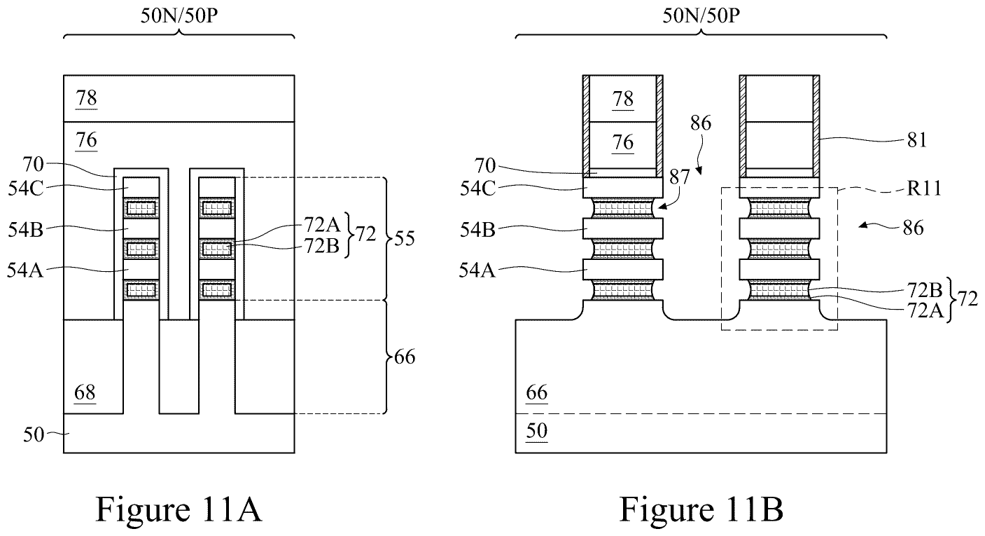

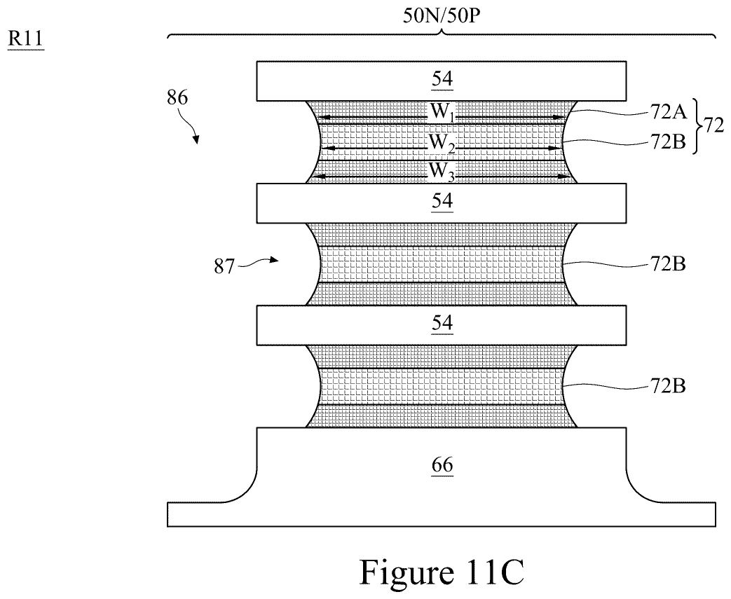

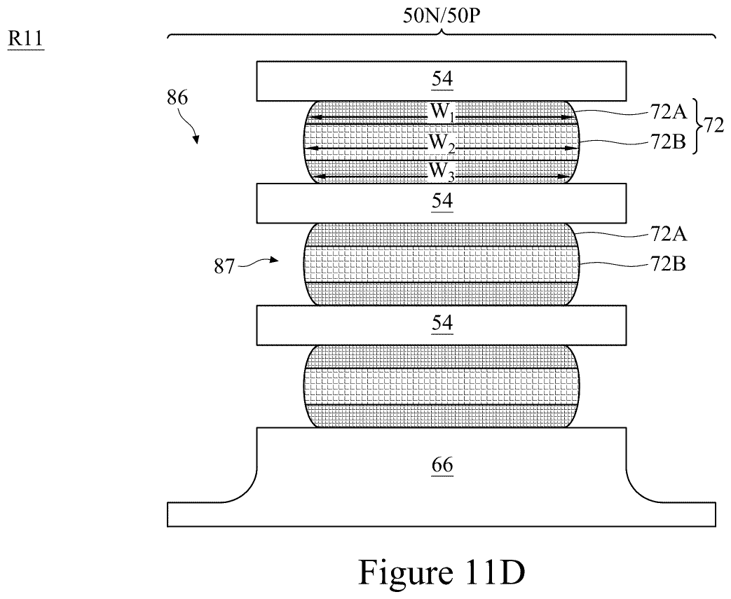

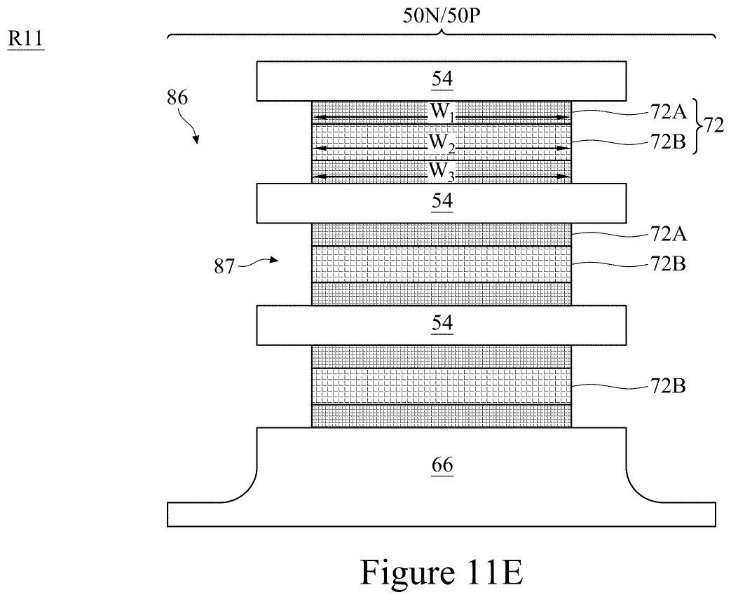

In FIGS. 11A-11E, the combined material layer 71 (e.g., the first material layer 71A and the second material layer 71B) may then be etched to form sacrificial material 72 (e.g., first sacrificial material segments 72A and a second sacrificial material segment 72B, collectively). The etching may be isotropic or anisotropic. For example, the combined material layer 71 may be etched by a wet etch process using diluted HF, or the like as an etchant. In some embodiments, the etching is performed to form notches 87 (e.g., recesses) in sidewalls of the sacrificial material 72 from sidewalls of the second nanostructures 54. Although the sidewalls of the sacrificial material 72 are illustrated as being concave in FIGS. 11B and 11C, the sidewalls may be convex (e.g., FIG. 11D) or straight (e.g., FIG. 11E).

FIGS. 11C-11E illustrate exemplary views of region R11 of FIG. 11B,

including the second nanostructures 54, the fins 66, and the sacrificial material 72. The illustrated embodiments provide variations in profiles for the sidewalls of the sacrificial material 72 following the etch process based on etch rates of the first sacrificial material segment 72A and the second sacrificial material segment 72B.

Referring to FIG. 11C (and FIG. 11B), the etch process may form the sidewalls of the sacrificial material 72 with concave (e.g., U-shaped) profiles. For example, the etch process may include an etchant selected to etch the second material layer 71B at a higher rate than the first material layer 71A. In addition, this effect may be increased by the etchant reaching the second material layer 71B more easily than the first material layer 71A. As illustrated, one of the first sacrificial material segments 72A may have a lateral width W₁ and the other of the first sacrificial material segments 72A may have a lateral width W₃, wherein the width W₁ and the width W₃ may be substantially the same or different. In addition, the second sacrificial material segment 72B may have lateral a width W₂ which is different from (e.g., less than) the width W₁ and the width W₃. In particular, an average of the widths W₁ and W₃ is greater than the width W₂. Further, a ratio W₁: W₂ or W₃: W₂ may range from 1 to 3. Note that these ratios being greater than 1 provide the concave profile that achieves many of the advantages discussed throughout the disclosure. In addition, these ratios being less than or equal to 3 allow for a sufficient geometry of the notches 87 to adequately form inner spacers in the notches 87 in subsequent steps. Further, these ratios being less than or equal to 3 ensure that the first sacrificial material segment 72A can be adequately removed during a gate replacement process in subsequent steps.

Referring to FIG. 11D, the etch process may form the sidewalls of the sacrificial material 72 with convex (e.g., rounded or round-shaped) profiles. For example, the etch process may include an etchant selected to etch the first material layer 71A at a higher rate than the second material layer 71B. Similarly as above, one of the first sacrificial material segments 72A may have a lateral width W₁ and the other of the first sacrificial material segments 72A may have a lateral width W₃, wherein the width W₁ and the width W₃ may be substantially the same or different. In addition, the second sacrificial material segment 72B may have a lateral width W₂ which is different from (e.g., greater than) the width W₁ and the width W₃. In particular, an average of the widths W₁ and W₃ is less than the width W₂. Further, a ratio W₂: W₁ or W₂: W₃ may range from 1 to 3. Note that these ratios being greater than 1 provide the convex profile that achieves advantages relating to stress modulation in the second nanostructures (e.g., channel regions) and/or the subsequently formed source/drain regions. In addition, these ratios being less than or equal to 3 allow for a sufficient geometry of the notches 87 to adequately form inner spacers in the notches 87 in subsequent steps.

Referring to FIG. 11E, the etch process may form the sidewalls of the sacrificial material 72 with straight (e.g., square-shaped) profiles. For example, the etch process may include an etchant selected to etch the first sacrificial material layer 71A and the second sacrificial material layer 71B at substantially the same rate. In some embodiments, the etchant may etch the material of the first sacrificial material layer 71A at a higher rate than the material of the second sacrificial material layer 71A in order to counter balance the fact that the etchant will reach the second sacrificial material layer 71B more easily than the first sacrificial material layer 71A. Similarly as above, one of the first sacrificial material segments 72A may have a lateral width W₁ and the other of the first sacrificial material segments 72A may have a lateral width W₃ , wherein the width W₁ and the width W₃ may be substantially equal. In addition, the second sacrificial material segment 72B may have a lateral width W₂ which is substantially equal to the width W₁ and the width W₃. In particular, an average of the widths W₁ and W₃ is substantially equal to the width W₂.

Referring to FIGS. 11C-11E collectively, in some embodiments, the etch process may include more than one etch step, wherein a first etch step uses an etchant which etches one of the layers 71A/71B at a significantly higher rate than the other, and a second etch step uses an etchant which etches the latter of the layers 71A/71B at a significantly higher rate than the former. In other embodiments, the first etch step may use an etchant which etches the layers 71A/71B at substantially the same rate and the second etch step may use an etchant which etches one of the layers 71A/71B at a significantly higher rate, or vice versa, to achieve the desired profile (e.g., concave or convex). Regarding these various embodiments, durations of the etch steps may be selected to form the desired profiles.

Note that the process steps of FIGS. 8A-11E are optional in that they may be performed for some of the nano-FETs and not others. For example, in some embodiments (not specifically illustrated), some of the first nanostructures 52 are not removed at this point in the process, and the material layer 71 is therefore not deposited for those eventual nano-FETs. Instead, an etch process is performed to recess sidewalls of the first nanostructures 52 to form notches 87 in those first nanostructures 52. This etch process may be performed similarly as described above in connection with FIGS. 8A and 8B (e.g., removal of the first nanostructures 52) or FIGS. 11A-11E (e.g., formation of the notches 87 in the sacrificial material 72). Note that this etch process is performed with a suitable etchant for the material of the first nanostructures 52 and is halted at a desired degree of recessing to form the notches 87 rather than completely removing the first nanostructures 52. In some embodiments, the etch process is an anisotropic etch process such as RIE, NBE, or the like. Note that subsequent figures illustrate the intermediate structures as including the sacrificial material 72. It should be appreciated that the corresponding shapes and dimensions of the first nanostructures 52 may be analogous to those illustrated for the sacrificial material 72, except as otherwise described. As such, labels in the figures for the sacrificial material 72 (or portions thereof) may generally apply to the first nanostructures 52 (or portions thereof).

Replacing the first nanostructures 52 with the sacrificial material 72 may provide advantages. For example, in subsequent source/drain formation steps, one or more high temperature processes may be performed to, for example, activate the dopants in the source/drain regions. When the material of the first nanostructures 52 (e.g., SiGe) is exposed to high temperatures, germanium intermixing and increased roughness at an interface between the first nanostructures 52 and second nanostructures 54 may result. Such manufacturing defects may degrade the performance of the resulting transistor devices. For example, when germanium diffuses into the second nanostructures 54, germanium residue may remain in channel regions of the resulting transistor devices, which negatively affects the performance of the channel regions. By replacing the first nanostructures 52 with an insulating material prior to the high temperature processes (e.g., source/drain annealing), manufacturing defects can be reduced and device performance can be improved (e.g., increased current drive, reduced capacitance, and improved short channel effect).

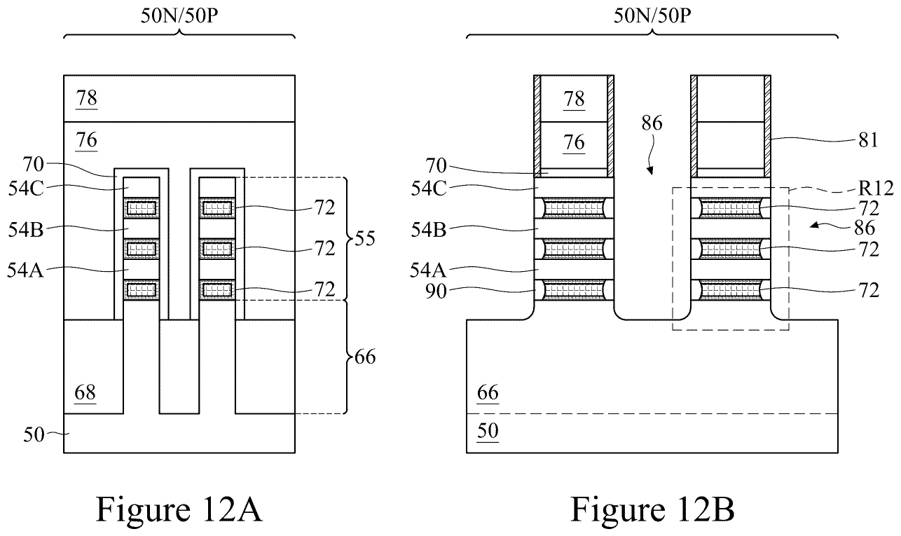

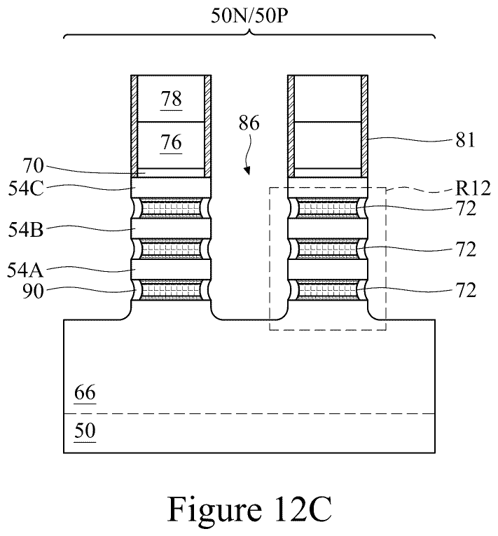

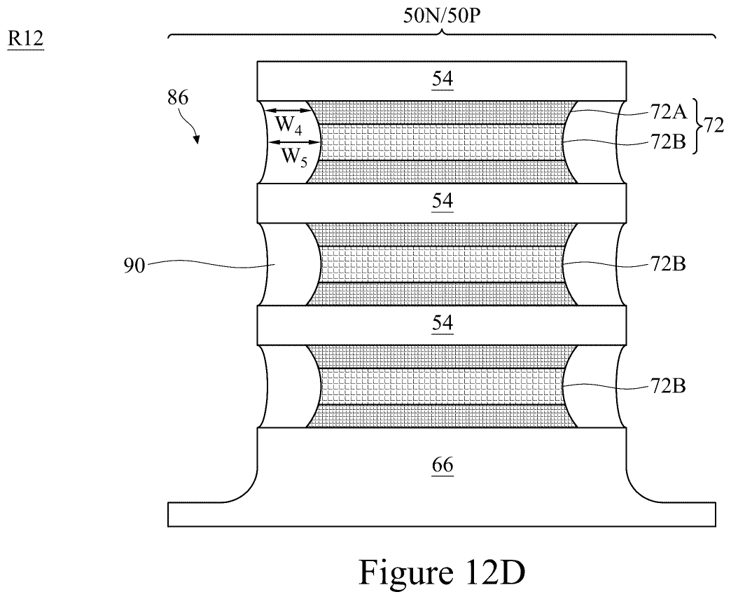

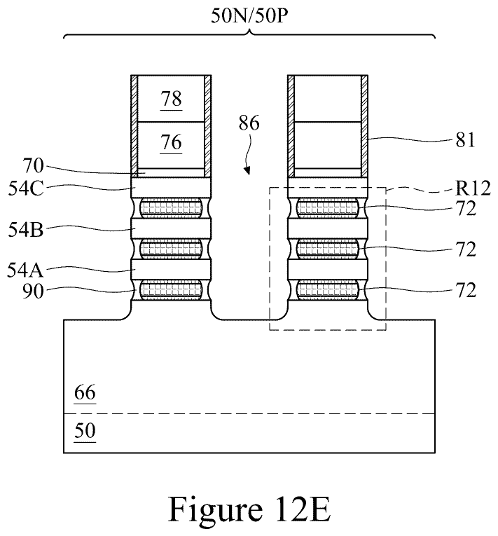

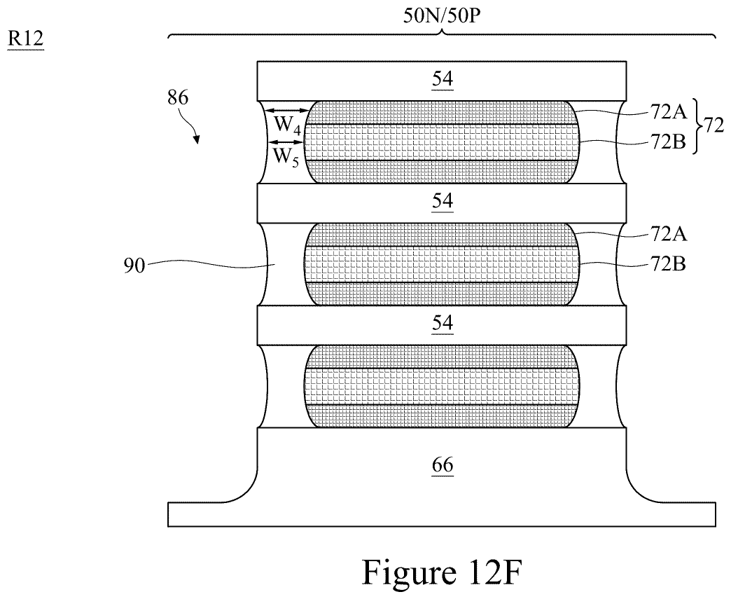

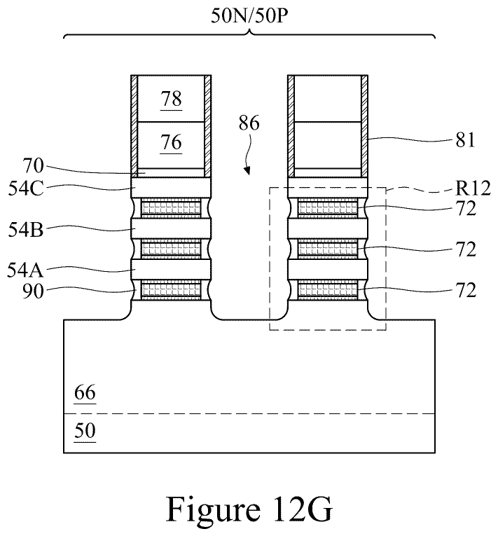

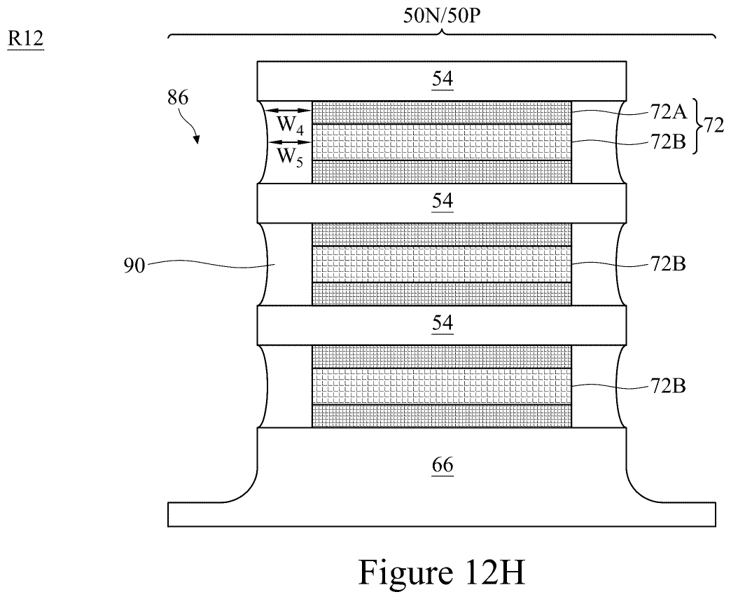

In FIGS. 12A-12H, inner spacers 90 are formed in the notches 87 on the sidewalls of the sacrificial material 72. The inner spacers 90 act as isolation features between subsequently formed source/drain regions and a gate structure. As will be discussed in greater detail below, source/drain regions will be formed in the first recesses 86, and the sacrificial material 72 will be replaced with corresponding gate structures. The inner spacers 90 may also be used to prevent damage to the subsequently formed source/drain regions during subsequent etching processes, such as etching processes used to form gate structures.

The inner spacers 90 may be formed by depositing an inner spacer layer (not separately illustrated) over the structures illustrated in FIGS. 11A-11E. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 90. The inner spacer layer may be etched by an anisotropic etching process, such as RIE, NBE, or the like.

FIGS. 12C-12H illustrate other exemplary embodiments after forming the inner spacers 90. For example, FIG. 12D illustrates an exemplary view of region R12 of FIG. 12C, FIG. 12F illustrates an exemplary view of region R12 of FIG. 12E, and FIG. 12H illustrates an exemplary view of region R12 of FIG. 12G. The illustrated embodiments provide variations in profiles for the outward sidewalls of the inner spacers 90. As such, although outward sidewalls of the inner spacers 90 are illustrated in FIG. 12B as being flush with sidewalls of the second nanostructures 54, the outward sidewalls of the inner spacers 90 may extend beyond or be recessed from the sidewalls of the second nanostructures 54 (see, e.g., FIGS. 12C-12H). For example, the outward sidewalls of the inner spacers 90 may be concave or convex.

FIGS. 12C and 12D represent embodiments in which the sidewalls of the sacrificial material 72 are concave, the outward sidewalls of the inner spacers 90 are concave, and the inner spacers 90 are recessed from the sidewalls of the second nanostructures 54. In some embodiments (not specifically illustrated), the outward sidewalls of the inner spacers 90 may be convex or straight, and/or the outward sidewalls of the inner spacers 90 may be recessed from or flushed with the sidewalls of the second nanostructures 54. As illustrated, the inner spacers 90 may have a lateral width W₄ adjacent to the first sacrificial material segment 72A and a lateral width W₅ adjacent to the second sacrificial material segment 72B. The width W₅ may be greater than or substantially equal to the width W₄ whether the outward sidewalls of the inner spacers 90 are concave, convex, or straight.

FIGS. 12E and 12F represent embodiments in which the sidewalls of the sacrificial material 72 are convex, the outward sidewalls of the inner spacers 90 are concave, and the inner spacers 90 are recessed from the sidewalls of the second nanostructures 54. In some embodiments (not specifically illustrated), the outward sidewalls of the inner spacers 90 may be convex or straight, and/or the outward sidewalls of the inner spacers 90 may be recessed from or flushed with the sidewalls of the second nanostructures 54. As illustrated, the inner spacers 90 may have a lateral width W₄ adjacent to the first sacrificial material segment 72A and a lateral width W₅ adjacent to the second sacrificial material segment 72B. The width W₄ may be greater than the width W, whether the outward sidewalls of the inner spacers 90 are concave, convex, or straight.

FIGS. 12G and 12H illustrate an embodiment in which the sidewalls of the sacrificial material 72 are straight, the outward sidewalls of the inner spacers 90 are concave, and the inner spacers 90 are recessed from the sidewalls of the second nanostructures 54. In some embodiments (not specifically illustrated), the outward sidewalls of the inner spacers 90 may be convex or straight, and/or the outward sidewalls of the inner spacers 90 may be recessed from or flushed with the sidewalls of the second nanostructures 54. As illustrated, the inner spacers 90 may have a lateral width W₄ adjacent to the first sacrificial material segment 72A and a lateral width W₅ adjacent to the second sacrificial material segment 72B. The width W₄ may be greater than the width W₅ when the outward sidewalls of the inner spacers 90 are concave, the width W₅ may be greater than the width W₄ when the outward sidewalls of the inner spacers 90 are convex, and the width W₄ and the width W₅ may be substantially equal when the outward sidewalls of the inner spacers 90 are straight.

Note that formation of the inner spacers 90 highlights various advantages of forming the sacrificial material 72 as described above. The sacrificial material 72 will be etched (e.g., forming the notches 87) with greater control to achieve desired sidewall profiles. In particular, the notches 87 may be formed more efficiently and with reduced risk of damage to the second nanostructures 54. In some embodiment profiles for the sacrificial material 72 (e.g., the concave profile), the first sacrificial material segments 72A may provide a physical barrier to protect the second nanostructures 54. In addition, the improved robustness of the sidewalls of the sacrificial material 72 improves formation of the inner spacers 90 in the notches 87. Further, the gate replacement process (as discussed in greater detail below) will be benefited by with a more efficient removal of the sacrificial material 72 (e.g., greater efficiency and reduced risk of damage to the second nanostructures 54) as well as smoother inward sidewalls of the inner spacers 90 upon which to form replacement gate structures.

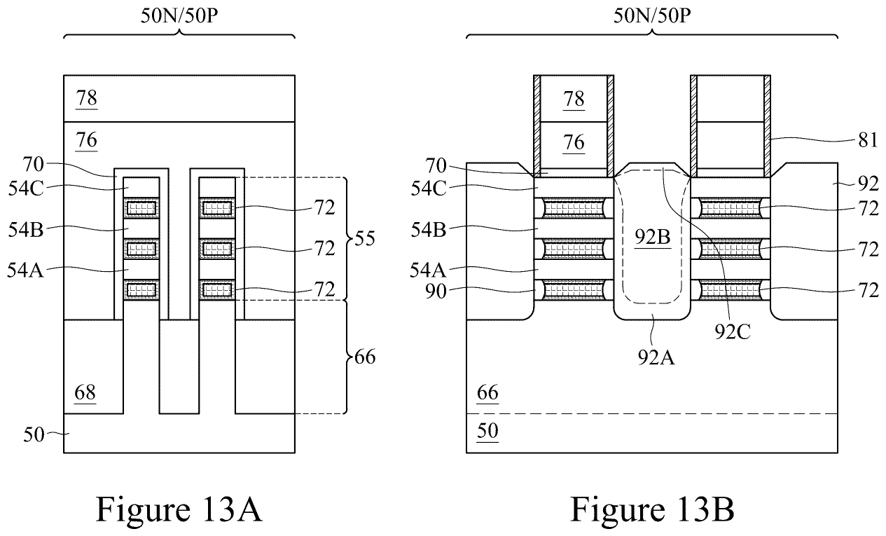

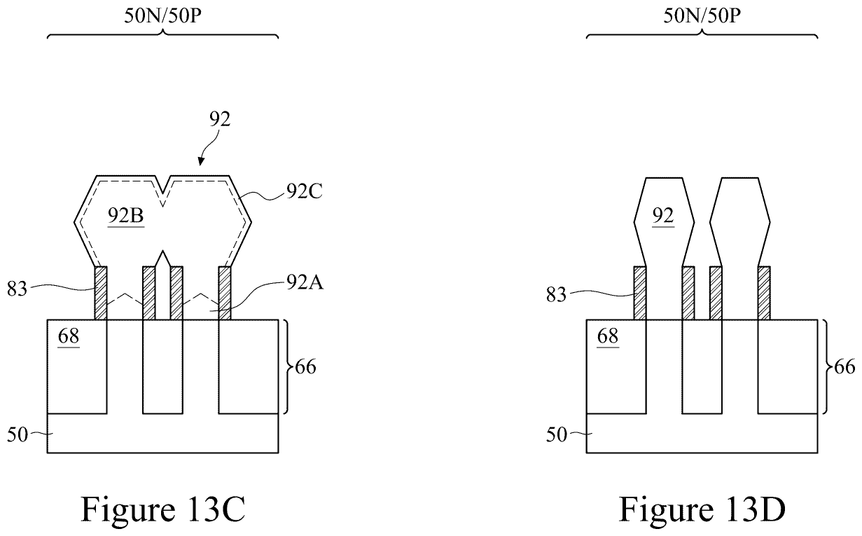

In FIGS. 13A-13D, epitaxial source/drain regions 92 are formed in the first recesses 86. In some embodiments, the source/drain regions 92 may exert stress on the second nanostructures 54 in the n-type region 50N and/or on the first nanostructures 52 in the p-type region 50P, thereby improving performance. As illustrated, the epitaxial source/drain regions 92 are formed in the first recesses 86 such that each dummy gate 76 is disposed between respective neighboring pairs of the epitaxial source/drain regions 92. In some embodiments, the gate spacers 81 are used to separate the epitaxial source/drain regions 92 from the dummy gates 76 and the inner spacers 90 are used to separate the epitaxial source/drain regions 92 from the sacrificial material 72 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs. For example, if the second nanostructures 54 are silicon, the epitaxial source/drain regions 92 in the n-type region 50N may include materials exerting a tensile strain on the second nanostructures 54, such as silicon, silicon carbide, phosphorous doped silicon carbide, silicon phosphide, or the like.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 in the p-type region 50P may include materials exerting a compressive strain on the second nanostructures 54, such as silicon-germanium, boron doped silicon-germanium, germanium, germanium tin, or the like.

The epitaxial source/drain regions 92, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

Referring to FIGS. 13C and 13D, as a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 13C. In other embodiments, adjacent epitaxial source/drain regions 92 remain separated after the epitaxy process is completed as illustrated by FIG. 13D. In the embodiments illustrated in FIGS. 13C and 13D, the fin spacers 83 may be formed on top surfaces of the STI regions 68, thereby blocking the epitaxial growth. In some other embodiments, the fin spacers 83 may cover portions of the sidewalls of the nanostructures 55 further blocking the epitaxial growth. In some other embodiments, the spacer etch used to form the fin spacers 83 may be adjusted to remove the spacer material to allow the epitaxially grown region to extend to the surface of the STI structures 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

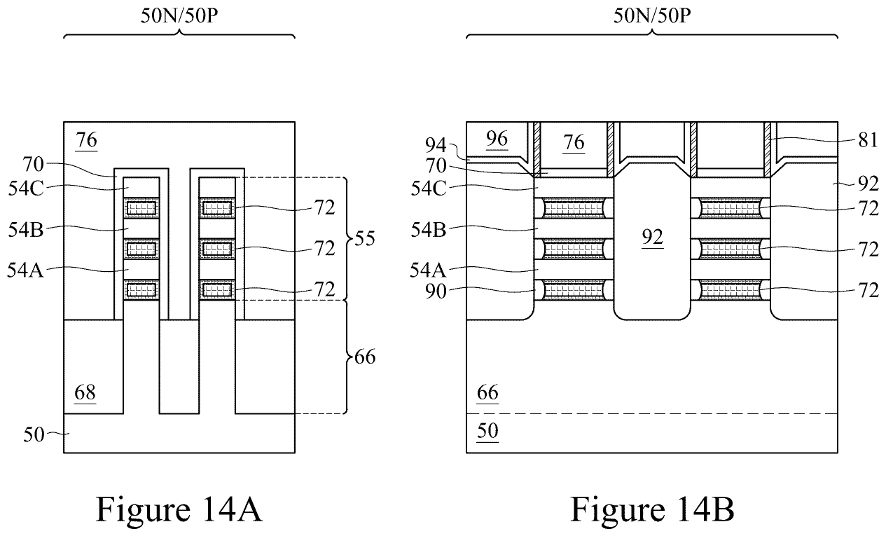

In FIGS. 14A and 14B, a first interlayer dielectric (ILD) 96 is deposited over the structure illustrated in FIGS. 13A and 13B, respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the gate spacers 81. The CESL 94 may comprise a dielectric material, such as, silicon nitride, silicon oxide, silicon oxynitride, or the like, having a different etch rate than the material of the overlying first ILD 96.

After the first ILD 96 is deposited, a planarization process, such as a CMP, may be performed to level the top surface of the first ILD 96 with the top surfaces of the dummy gates 76 or the masks 78. The planarization process may also remove the masks 78 on the dummy gates 76, and portions of the gate spacers 81 along sidewalls of the masks 78. After the planarization process, top surfaces of the dummy gates 76, the gate spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the gate spacers 81.

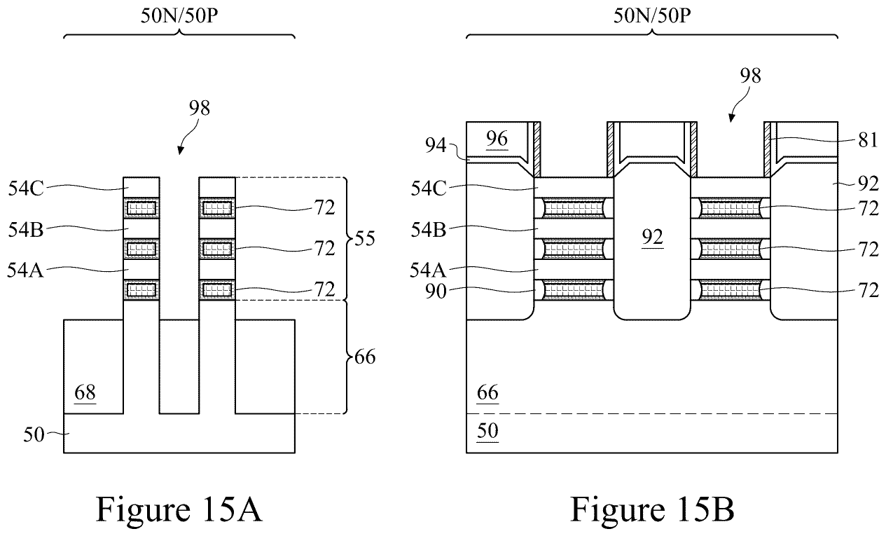

In FIGS. 15A and 15B, the dummy gates 76, and the masks 78 (if present), are removed in one or more etching steps, so that second recesses 98 are formed. Portions of the dummy gate dielectrics 70 and portions of the protective liner 60 in the second recesses 98 may also be removed. In some embodiments, the dummy gates 76 and the dummy gate dielectrics 70 are removed by an anisotropic dry etch process. For example, the etching process may include a dry etch process using reaction gas(es) that selectively etch the dummy gates 76 at a faster rate than the first ILD 96 or the gate spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 70 may be used as etch stop layers when the dummy gates 76 are etched. The dummy gate dielectrics 70 may then be removed after the removal of the dummy gates 76.

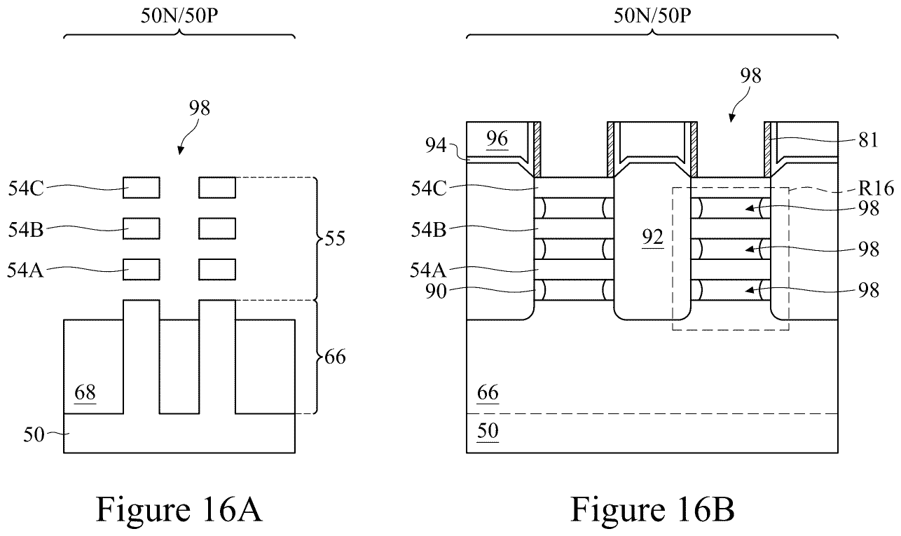

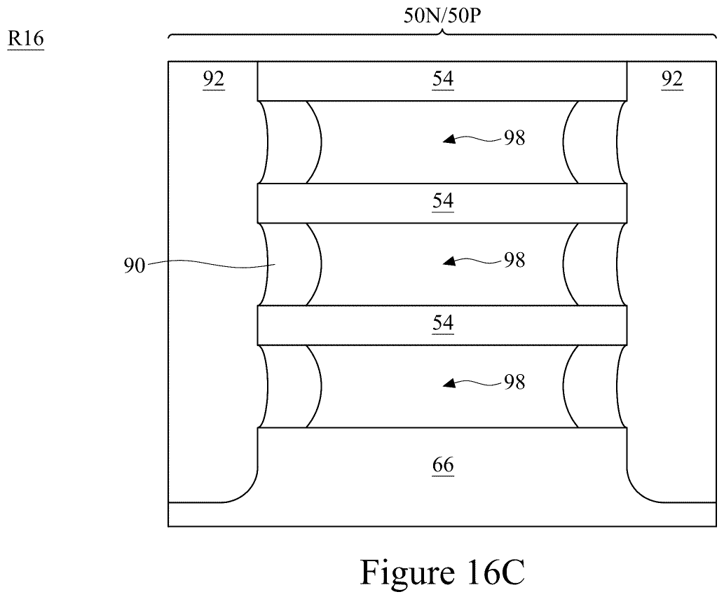

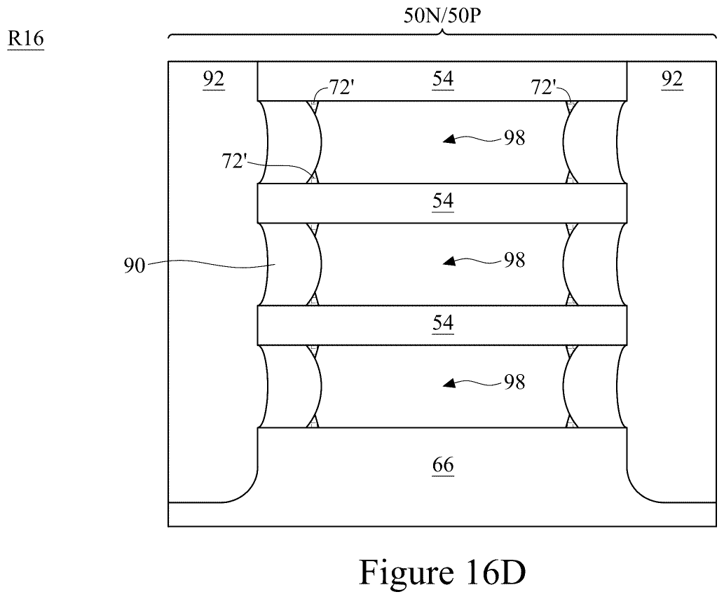

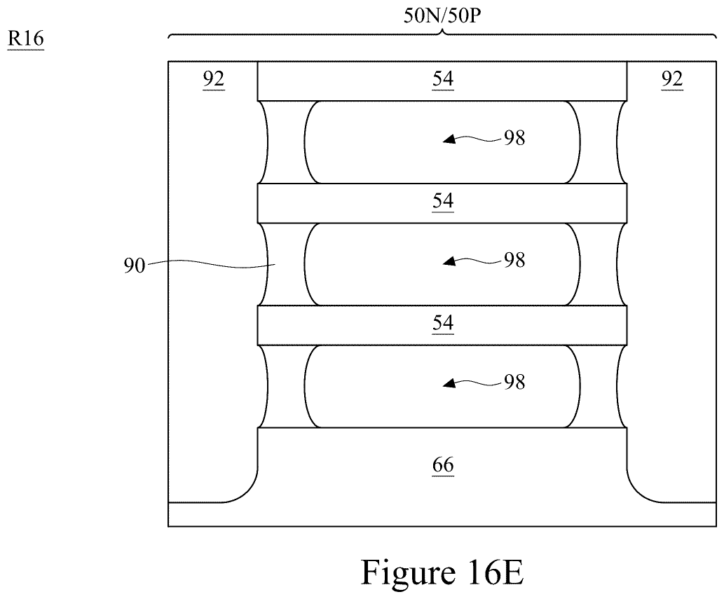

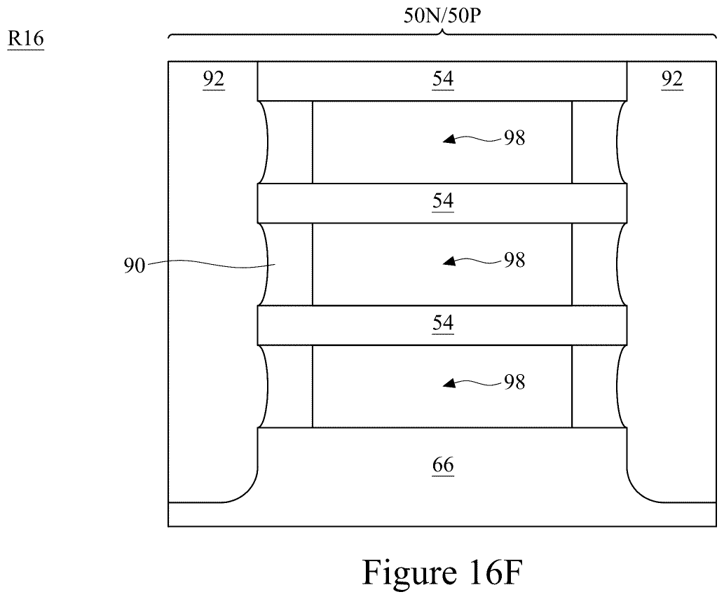

In FIGS. 16A-16F, the sacrificial material 72 is removed, extending the second recesses 98 between the second nanostructures 54. Removing the sacrificial material 72 may include performing an isotropic etching process such as wet etching or the like using etchants which are selective to the materials of the sacrificial material 72, while the second nanostructures 54 remain relatively unetched as compared to the sacrificial material 72. As illustrated, extending the second recesses 98 may expose inward facing sidewalls of the inner spacers 90. The sacrificial material 72 may be completely removed, or a residue of the sacrificial material 72′ may remain in corners of the inner spacers 90 and the second nanostructures 54 in the second recesses 98 (see, e.g., FIG. 16D).

In some embodiments, the STI regions 68 may be etched while removing the sacrificial material 72, but the total amount of loss in the STI regions 68 may be reduced by controlling etching parameters (e.g., timing) while removing the sacrificial material 72. In other embodiments, the STI regions 68 may include a hard mask (not separately illustrated) at a top surface to protect the underlying STI regions 68 from etching while patterning and removing the sacrificial material 72. In such embodiments, the hard mask may comprise, for example, a nitride.

As illustrated, the etch process may expose the inward sidewalls of the inner spacers 90. The exposed inner spacers 90 remain substantially unetched due to a high etch selectivity between the material(s) of the sacrificial material 72 and the material of the inner spacer 90. As such, the inner spacer 90 protects the epitaxial source/drain regions 92 from being etched during removal of the sacrificial material 72.

FIGS. 16C-16F illustrate exemplary views of region R16 of FIG. 16B, including the second nanostructures 54, the fins 66, the inner spacers 90, the epitaxial source/drain regions 92, and the extended second recesses 98 after removal of the sacrificial material 72. In particular, the illustrated embodiments provide variations in profiles for the inward sidewalls of the inner spacers 90 following removal of the sacrificial material 72.

For example, FIGS. 16C and 16D illustrate removal of the sacrificial material 72 from the embodiments illustrated in FIGS. 12C and 12D. As such, the second recesses 98 will have an analogous shape that the sacrificial material 72 had (e.g., concave), wherein the inward sidewalls of the inner spacers 90 maintain a convex shape. In accordance with similar embodiments, FIG. 16D illustrates that residues of the sacrificial material 72′ may remain on sidewalls of the inner spacers 90, such as in corners of the inner spacers 90 and the second nanostructures 54 (or the fins 66). This feature is notable in embodiments in which etching the sacrificial material 72 (see FIGS. 11A-11E) results in concave sidewalls (e.g., FIGS. 11B and 11C), which provide narrower corners between the inner spacers 90 and the second nanostructures 54. As a result, the etchants may have more difficulty reaching these narrower corners to fully remove the sacrificial material 72.

In addition, FIG. 16E illustrates removal of the sacrificial material 72 from the embodiments illustrated in FIGS. 12E and 12F. As such, the second recesses 98 will have an analogous shape that the sacrificial material 72 had (e.g., convex), while the inward sidewalls of the inner spacers 90 maintain a concave shape. Further, FIG. 16F illustrates removal of the sacrificial material 72 from the embodiments illustrated in FIGS. 12G and 12H. As such, the second recesses 98 will have an analogous shape that the sacrificial material 72 had (e.g., straight), while the inward sidewalls of the inner spacers 90 maintain a straight shape as well. It should be appreciated that, in some embodiments (not specifically illustrated), residues of the sacrificial material 72′ may also remain in the embodiments illustrated in FIGS. 16E and 16F.

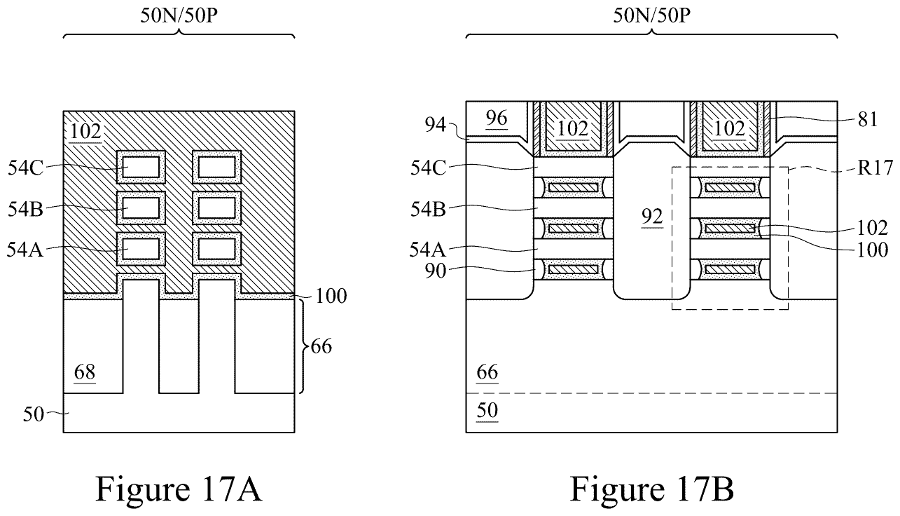

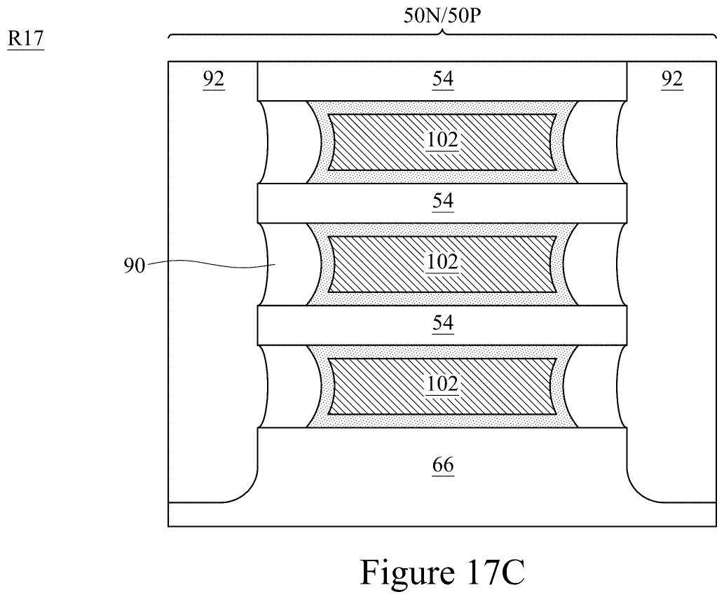

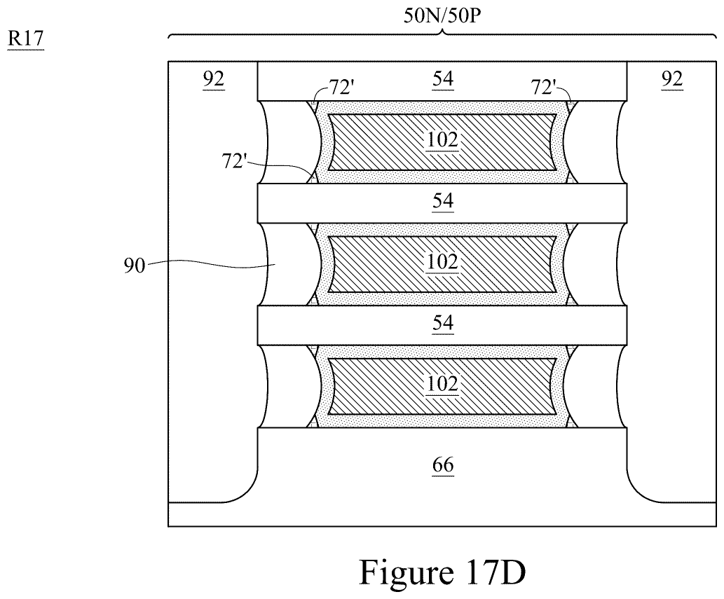

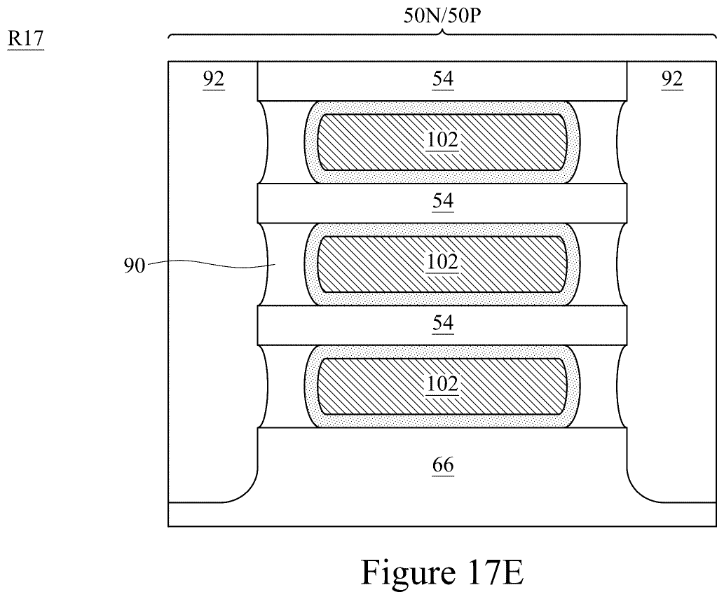

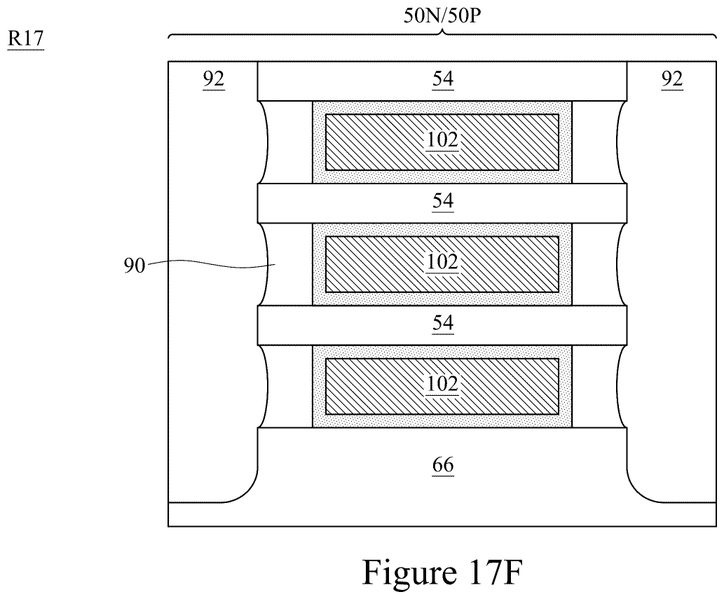

In FIGS. 17A-17F, gate dielectric layers 100 and gate electrodes 102 are formed for replacement gates. The gate dielectric layers 100 are deposited conformally in the second recesses 98. The gate dielectric layers 100 may be formed on top surfaces and sidewalls of the substrate 50, on top surfaces, sidewalls, and bottom surfaces of the second nanostructures 54, and on the inward sidewalls of the inner spacers 90 (if exposed). The gate dielectric layers 100 may also be deposited on top surfaces of the first ILD 96, the CESL 94, the gate spacers 81, and the STI regions 68.

In accordance with some embodiments, the gate dielectric layers 100 comprise one or more dielectric layers, including an oxide, a metal oxide, the like, or combinations thereof. For example, in some embodiments, the gate dielectric layers 100 may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

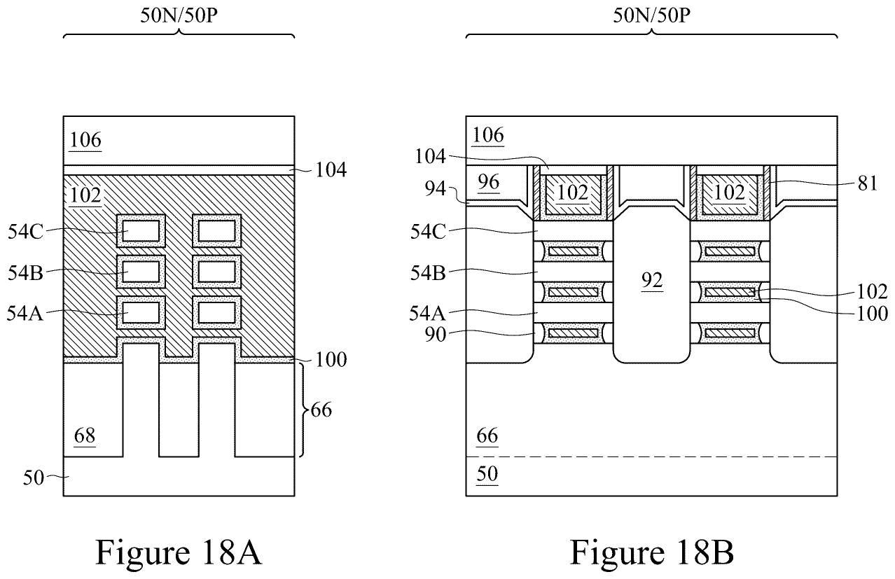

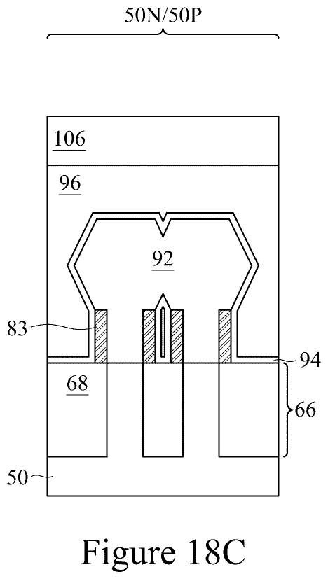

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 18A-18D, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes. As illustrated, the gate dielectric layers 100 may deposit along the inward sidewalls of the inner spacers 90 as well as along upper and lower surfaces of the second nanostructures 54 (and upper surfaces of the fins 66). As a result, the inner spacers 90 may be bounded by the epitaxial source/drain region 92, the second nanostructures 54, and the gate dielectric layers 100.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

FIGS. 17C-17F illustrate exemplary views of region R17 of FIG. 17B, including the second nanostructures 54, the fins 66, the inner spacers 90, the epitaxial source/drain regions 92, the gate dielectric layers 100, and the gate electrode 102. In particular, the illustrated embodiments provide variations in profiles for the replacement gate features formed in the second recesses 98. FIGS. 17C-17F illustrate formation of the gate structures (e.g., the gate dielectric layers 100 and the gate electrode 102) on the embodiments illustrated in FIGS. 16C-16F, respectively. Note that, as illustrated by FIG. 17D, the residue of the sacrificial material 72′ may remain on the inner spacers 90, such as between the inner spacers 90 and the gate dielectric layers 100. As discussed above, the sacrificial material residue 72′ may remain, and the gate dielectric layers 100 may be formed on the sacrificial material residue 72′. The sacrificial material residue 72′ is an insulating material (e.g., silicon oxide) and may have little to no impact on the electrical performance of the resulting device.

In accordance with some embodiments, the gate structures have dimensions that are substantially equal to the dimensions of the corresponding sacrificial material 72 described above. For example, the widths W₁/W₂/W₃ of the sacrificial material 72 (see FIGS. 11C-11E) may generally apply to the gate structures. It should be appreciated, however, that the analogous width W₁ of the gate structure may be less than the width W₁ of the sacrificial material 72 if some of the sacrificial material residue 72′ remains after removal of the sacrificial material 72.

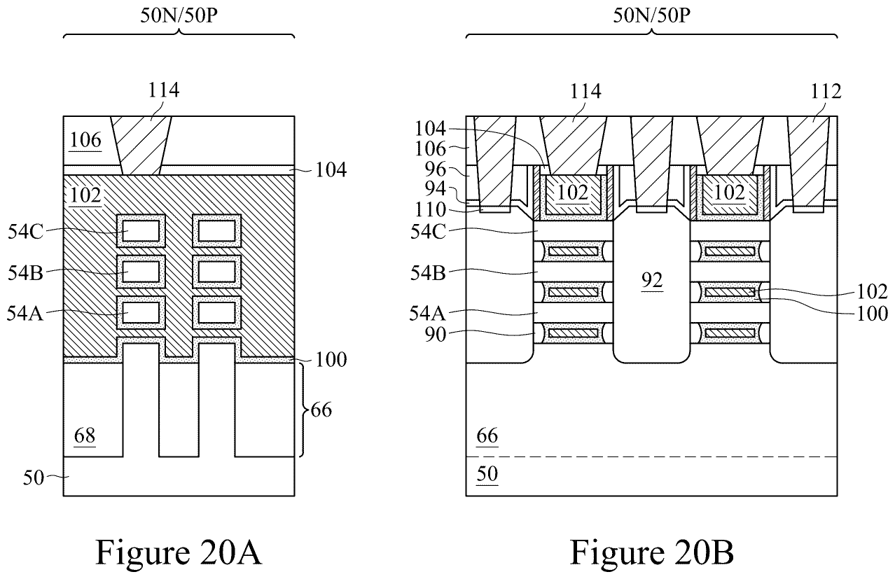

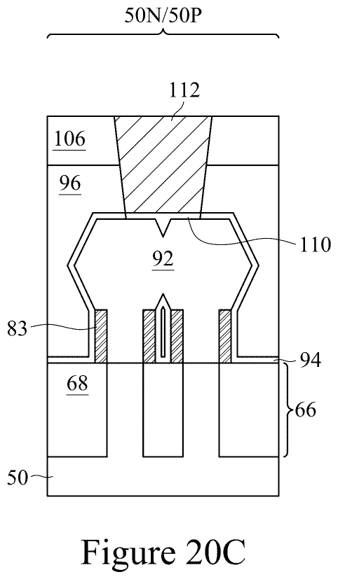

In FIGS. 18A-18C, the gate structure (e.g., the gate dielectric layers 100 and the gate electrodes 102) is recessed, so that a recess is formed directly over the gate structure and between opposing portions of the gate spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 20A-20C) penetrate through the gate mask 104 to contact the top surface of the recessed gate electrodes 102.

As further illustrated, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

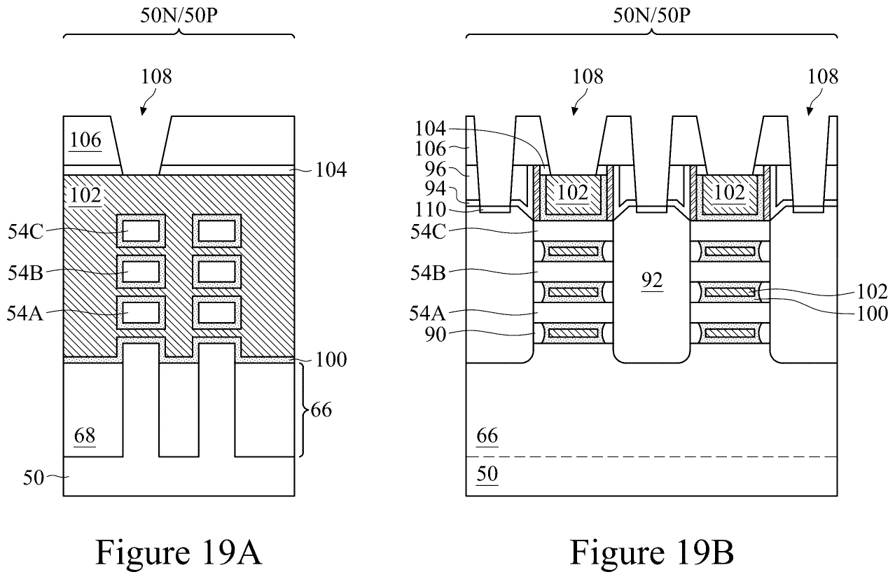

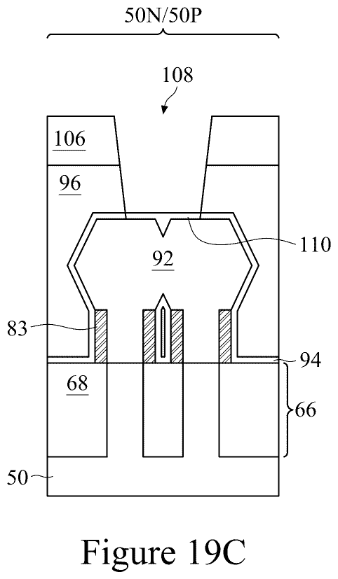

In FIGS. 19A-19C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask (not specifically illustrated), such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIGS. 19B illustrate the third recesses 108 as exposing the epitaxial source/drain regions 92 and the gate structure in a same cross-section, in various embodiments, the epitaxial source/drain regions 92 and the gate structure may be exposed in different cross-sections, thereby reducing the risk of shorting subsequently formed contacts.

After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

In FIGS. 20A-20C, contacts 112 and 114 (also referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and is electrically coupled to the underlying conductive feature (e.g., gate electrode 102 and/or silicide region 110 in the illustrated embodiment). The contacts 114 are electrically coupled to the gate electrode 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

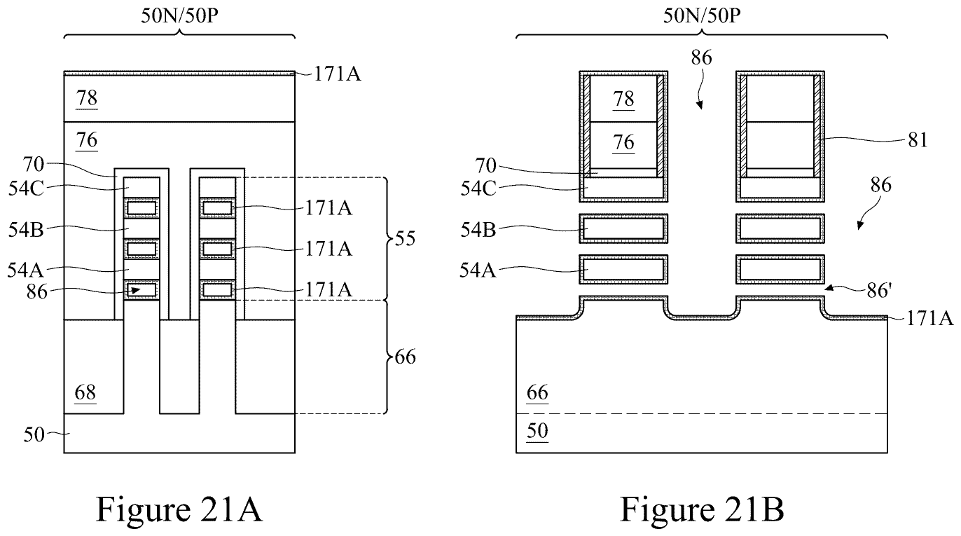

FIGS. 21A-26G illustrate embodiments for forming sacrificial material 172 after removal of the first nanostructures 52 as described above in connection with FIGS. 8A and 8B. For example, a multi-deposition process (e.g., triple-deposition or greater) may be used to form a material layer 171 (e.g., a first material layer 171A, a second material layer 171B, and a third material layer 171C). As discussed in greater detail below, the layers 171A/171B/171C may be formed with varying etch selectivities in order to provide improved control over the profile of outward sidewalls of the sacrificial material 72. Some of the layers 171A/171B/171C may be formed similarly as described in connection with analogous layers 71A/71B, unless otherwise specified below. In accordance with various embodiments, formation of the sacrificial material 172 achieves similar or same advantages as described above in connection with the sacrificial material 72. Indeed, the greater number of sacrificial material segments 172A/172B/172C may provide greater control of formation of the notches 87 as well as further improvements to other subsequent processes.

In FIGS. 21A and 21B, a first material layer 171A is deposited over and around the second nanostructures 54 in the recesses 86 and gaps 86′ where the first nanostructures 52 were removed. The first material layer 171A may be deposited by a conformal deposition process, such as ALD, CVD (e.g., FCVD), or the like. The first material layer 171A may comprise an insulating material such as silicon oxide (e.g., SiOₓ such as SiO₂), silicon nitride, silicon oxycarbide, silicon oxycarbonitride, or the like that can be selectively etched from the second nanostructures 54. In various embodiments, the first material layer 171A is free of germanium.

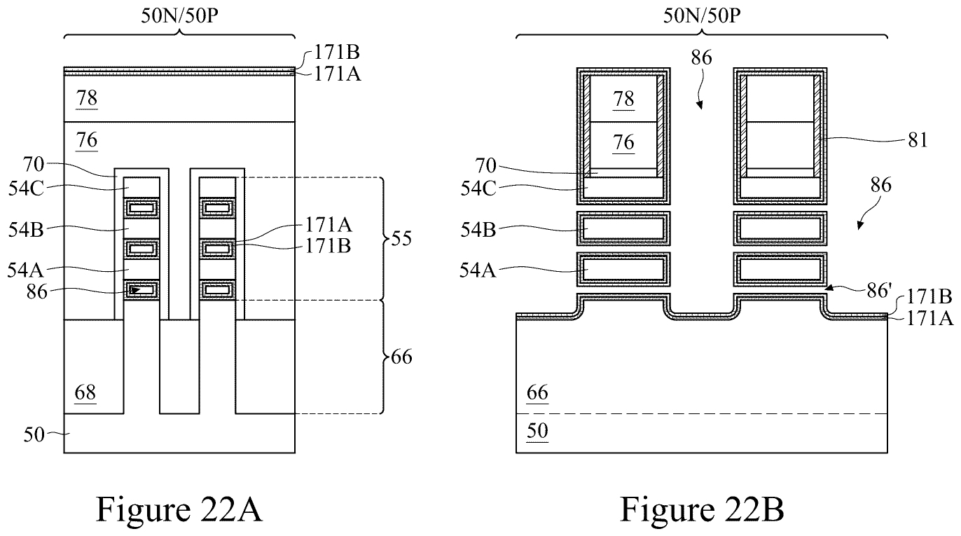

In FIGS. 22A and 22B, a second material layer 171B is deposited over the first material layer 171A in the recesses 86 and gaps 86′ between the second nanostructures 54. The second material layer 171B may be deposited by a conformal process, such as ALD, CVD (e.g., FCVD), or the like. The second material layer 171B may comprise an insulating material such as silicon oxide (e.g., SiOₓ such as SiO₂), silicon germanium, silicon nitride, silicon oxycarbide, silicon oxycarbonitride, or the like that can be selectively etched from the second nanostructures 54. A combined thickness of the first material layer 171A and the second material layer 171B may range from 1 nm to 2 nm. The combined thickness being about 1 nm or greater ensures full coverage over the second nanostructures 54 within the gaps 86′ of the recesses 86. The combined thickness being about 2 nm or less ensures that openings to the gaps 86′ of the recesses 86 are not blocked or pinched.

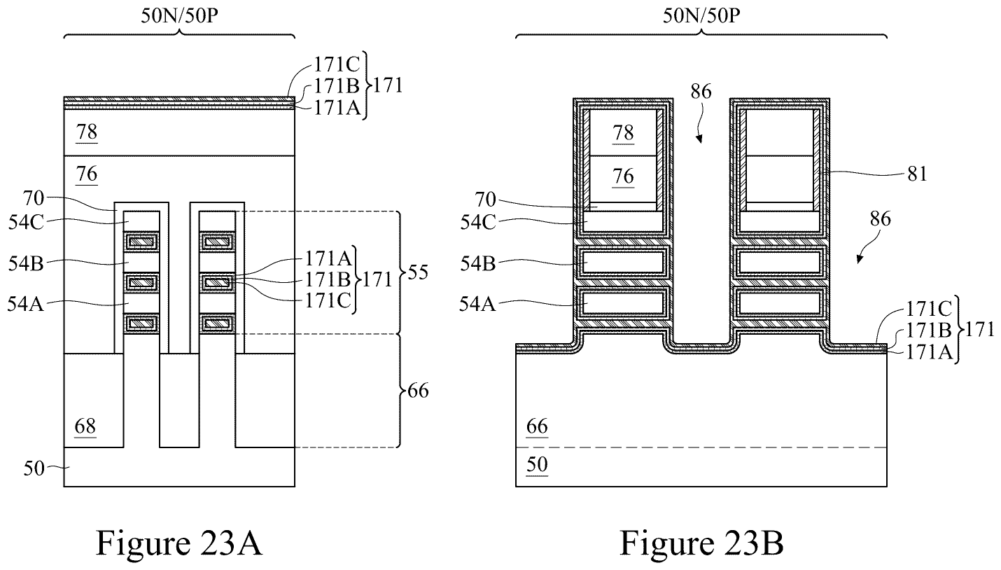

In FIGS. 23A and 23B, a third material layer 171C is deposited over the second material layer 171B in the recesses and gaps 86′ between the second nanostructures 54. In accordance with some embodiments, the third material layer 171C fills a remainder of the gaps 86′ of the recesses 86 between the second nanostructures 54. As illustrated, the resulting combined material layer 171 (e.g., the first material layer 171A, the second material layer 171B, and the third material layer 171C) comprises multi-layer portions (e.g., five-layer) between the second nanostructures 54. The third material layer 171C may be deposited by a conformal or gap-fill process, such as ALD, CVD (e.g., FCVD), or the like. The third material layer 171C may comprise an insulating material such as silicon oxide (e.g., SiOₓ such as SiO₂), silicon germanium, silicon nitride, silicon oxycarbide, silicon oxycarbonitride, or the like that can be selectively etched from the second nanostructures 54.

In accordance with various embodiments, the first material layer 171A, the second material layer 171B, and the third material layer 171C have different compositions and/or structures in order for the resulting layers 171A/171B/171C, which may therefore have different etch selectivities from one another. In some such embodiments, these layers 171A/171B/171C may be formed of the same material (e.g., silicon oxide or another listed above) using different processes. For example, the first material layer 171A and the second material layer 171B may be formed by ALD processes, and the third material layer 171C may be formed by either FCVD or ALD. In various embodiments, these layers 171A/171B/171 may be formed of same or different materials, same or different processes, or any combinations thereof. In particular, any suitable combinations of materials and processes may be utilized.

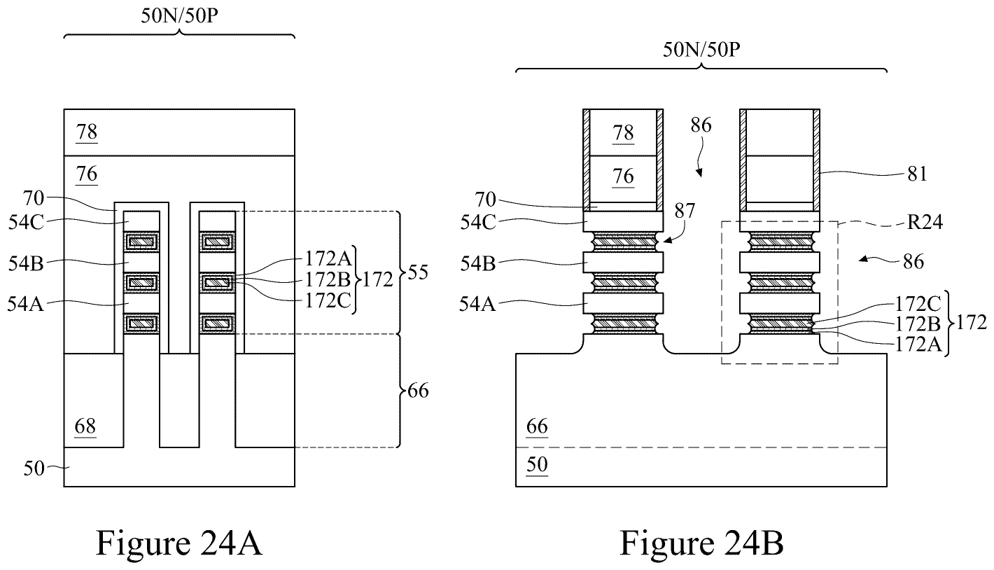

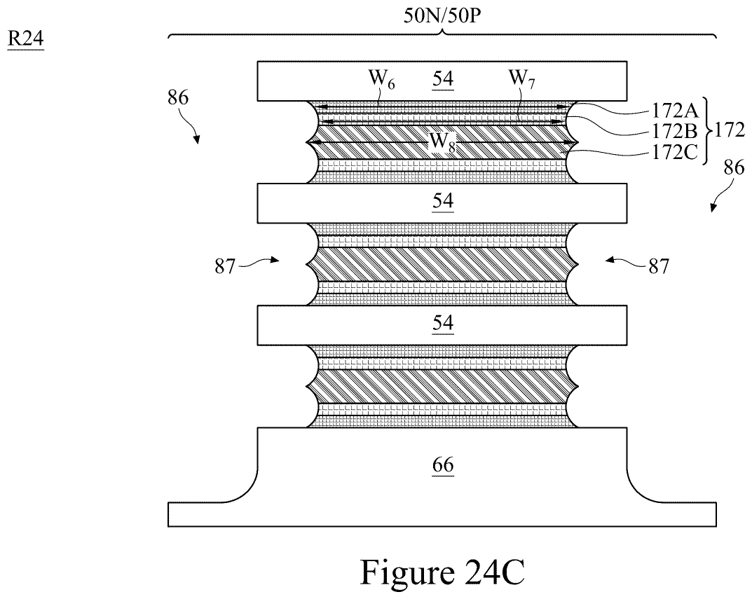

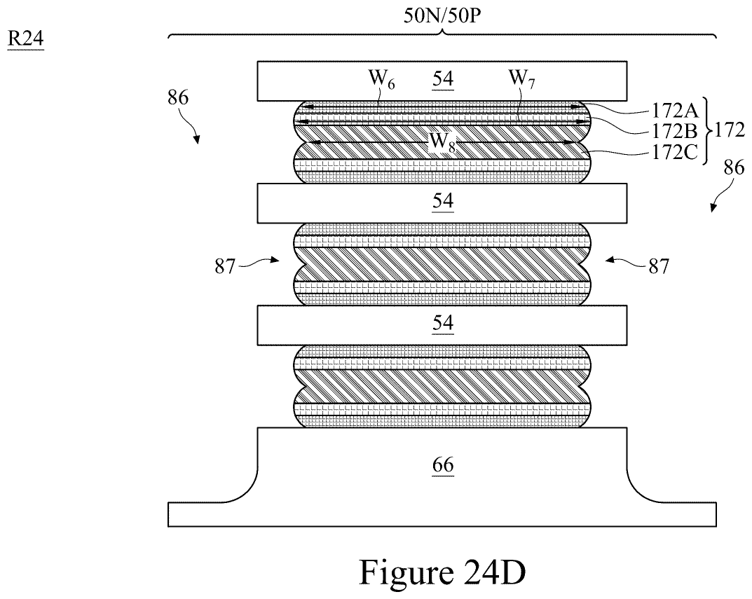

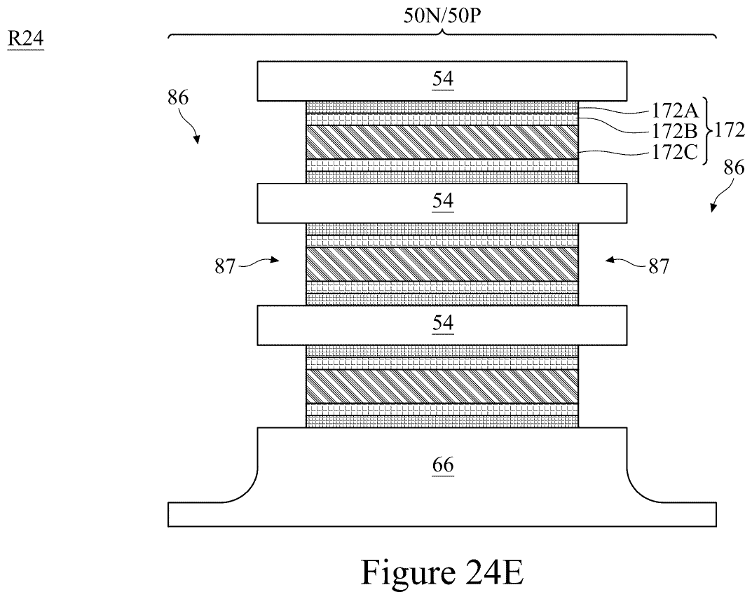

In FIGS. 24A-24E, the combined material layer 171 may then be etched to form sacrificial material 172 (e.g., comprising first sacrificial material segments 172A, second sacrificial material segments 172B, and a third sacrificial material segment 172C). The etching may be isotropic or anisotropic. For example, the combined material layer 171 may be etched by a wet etch process using diluted HF, or the like as an etchant. In some embodiments, the etching is performed to form notches 87 (e.g., recesses) in sidewalls of the sacrificial material 172 from sidewalls of the second nanostructures 54. Similarly as with the previous embodiments, the notches 87 may be concave, convex, or straight. In addition, the notches 87 may be formed to have other profiles, such as the notches 87 W-shapes or M-shapes between adjacent second nanostructures 54. Although the sidewalls of the sacrificial material 172 are illustrated as being concave (e.g., having W-shaped notches 87) in FIGS. 24B and 24C, the sidewalls may be convex (e.g., having M-shaped notches 87) as illustrated in FIG. 24D or straight as illustrated in FIG. 24E.

FIGS. 24C-24E illustrate exemplary views of region R24 of FIG. 24B, including the second nanostructures 54, the fins 66, and the sacrificial material 172. The illustrated embodiments provide variations in profiles for the sidewalls of the sacrificial material 172 following the etch process.

Referring to FIG. 24C (and FIG. 24B), the etch process may form the sidewalls of the sacrificial material 172 with W-shaped concave profiles. For example, the etch process may include an etchant selected to etch the second material layer 171B at a higher rate than the first material layer 171A and the third material layer 171C. This effect may be increased by the etchant having more difficulty reaching the first material layer 171B than the second material layer 171B. As illustrated, the first sacrificial material segment 172A may have a lateral width W₆, the second sacrificial material segment 172B may have a lateral width W₇, and the third sacrificial material segment 172C may have a lateral width W₈. In some embodiments, the width W₇ is less than the width W₆ and the width W₈. In addition, the width W₈ may be less than the width W₆. In particular, a ratio W₆: W₂ and/or a ratio W₈: W₇ may range from 1 to 3.

Referring to FIG. 24D, the etch process may form the sidewalls of the sacrificial material 172 with M-shaped convex profiles. For example, the etch process may include an etchant selected to etch the second material layer 171B at a lower rate than the first material layer 171A and the third material layer 171C. This effect may be reduced by the etchant having more difficulty reaching the first material layer 171B than the second material layer 171B. As illustrated, the first sacrificial material segment 172A may have a lateral width W₆, the second sacrificial material segment 172B may have a lateral width W₇, and the third sacrificial material segment 172C may have a lateral width W₈. In some embodiments, the width W₇ is greater than the width W₆ and the width W₈. In addition, the width W₈ may be less than the width W₆. In particular, a ratio W₇: W₆ and/or a ratio W₇: W₈ may range from 1 to 3.

Referring to FIG. 24E, the etch process may form the sidewalls of the sacrificial material 172 with straight profiles. For example, the etch process may include an etchant selected to etch the layers 171A/171B/171C at a substantially same rate, such as compensating for the etchant having greater difficulty reaching the first material layer 171A as compared to the second material layer 171B and the third material layer 171C. As such, each of the sacrificial material segments 172A/172B/172C may have substantially the same lateral width.

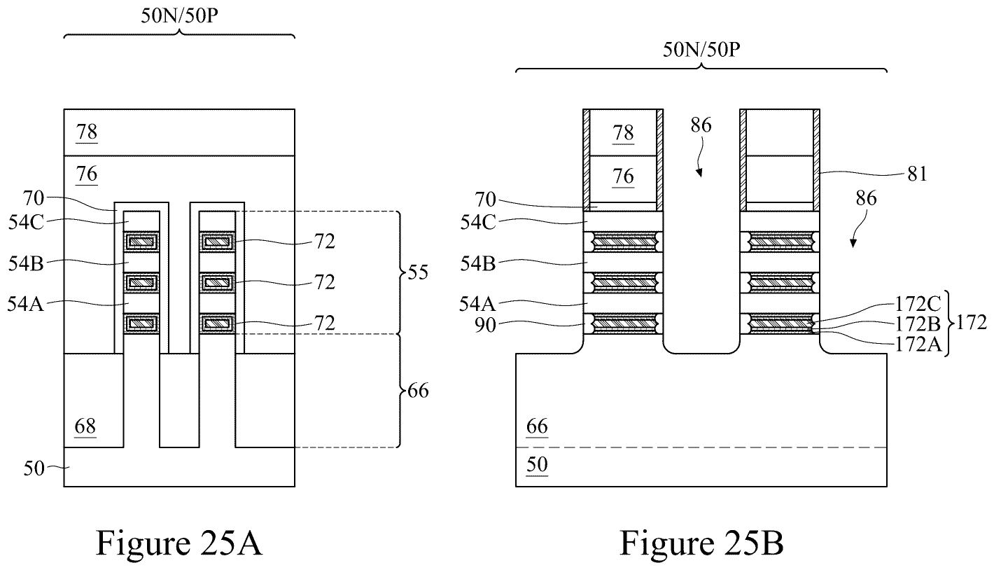

In FIGS. 25A and 25B, inner spacers 90 are formed in the notches 87 on the sidewalls of the sacrificial material 172, similarly as described above. The inner spacers 90 act as isolation features between subsequently formed source/drain regions and a gate structure. The inner spacers 90 may be formed by depositing an inner spacer layer (not separately illustrated) over the structures illustrated in FIGS. 24A-24F. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 90. The inner spacer layer may be etched by an anisotropic etching process, such as RIE, NBE, or the like.

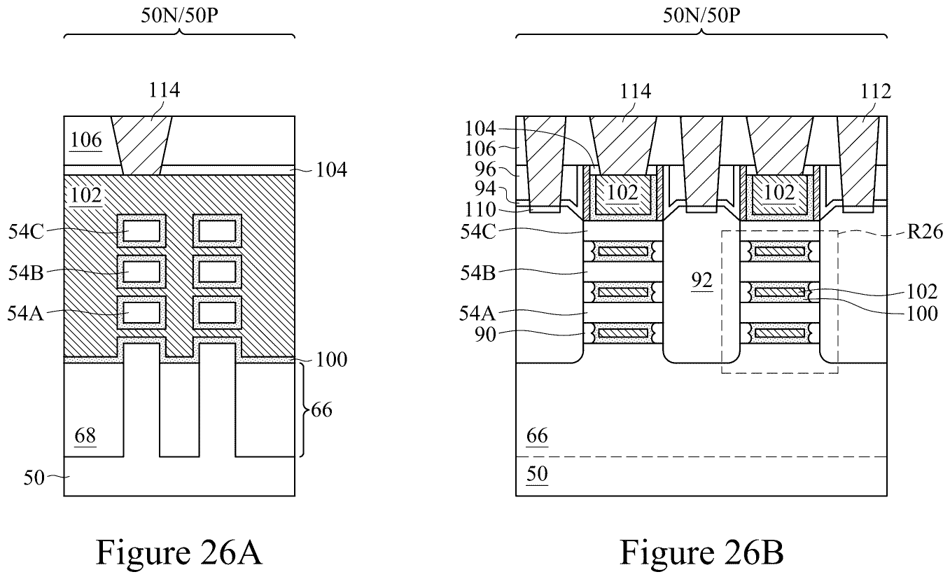

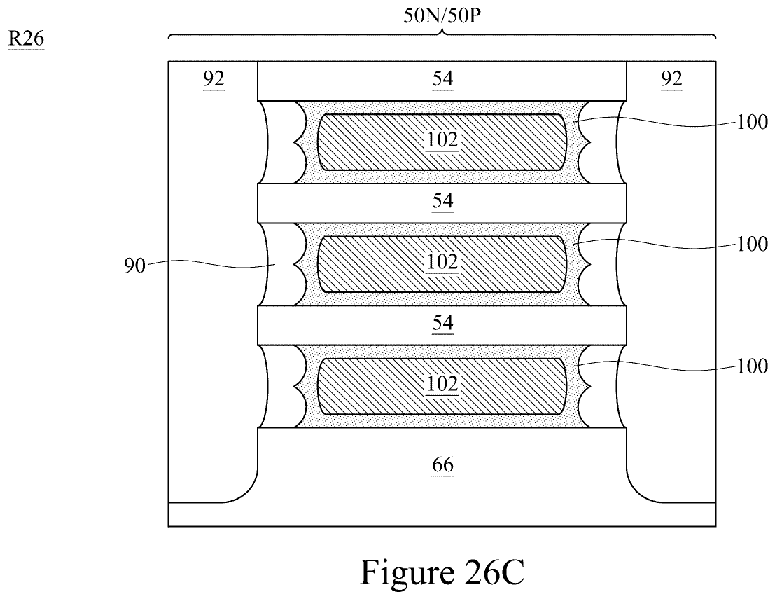

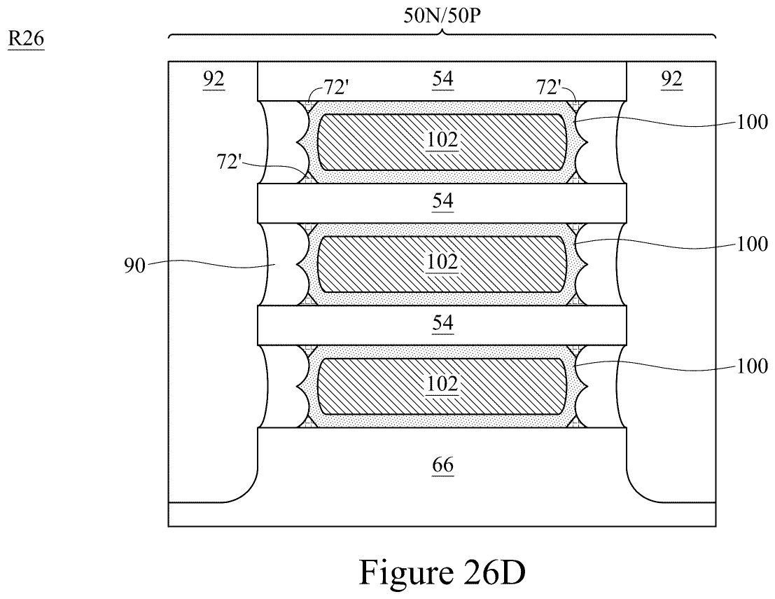

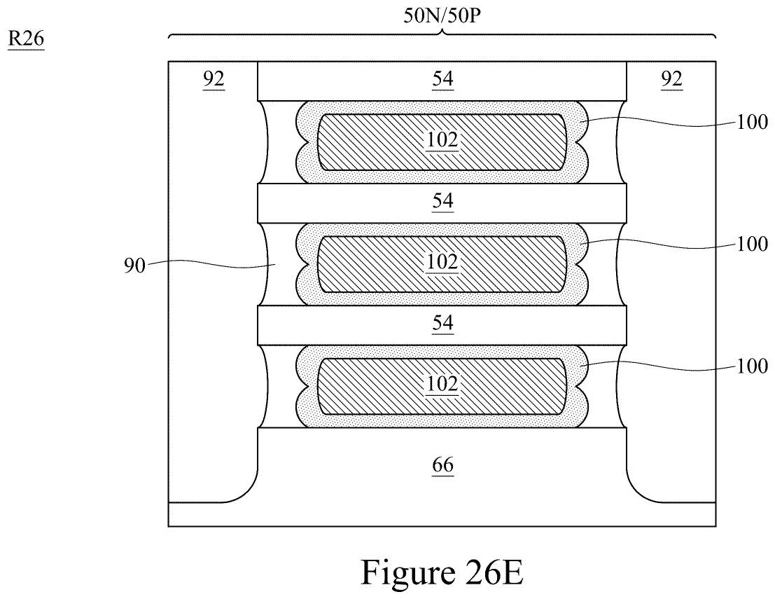

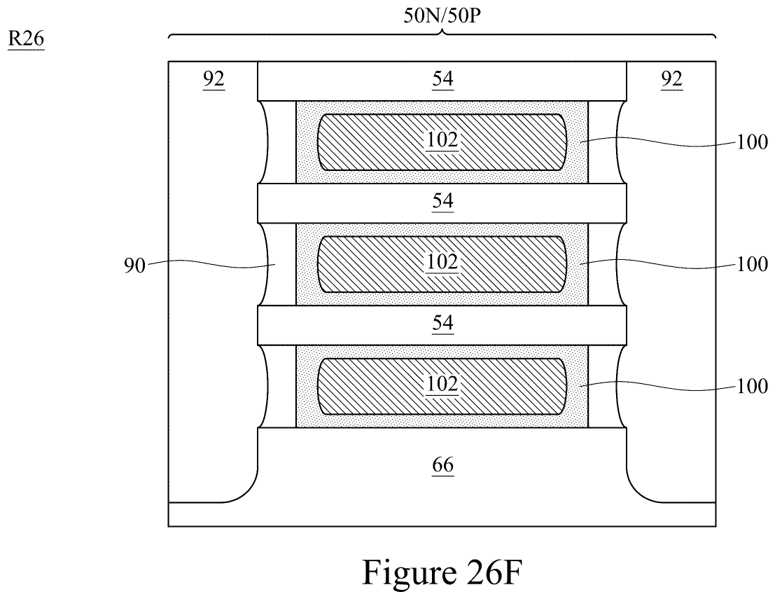

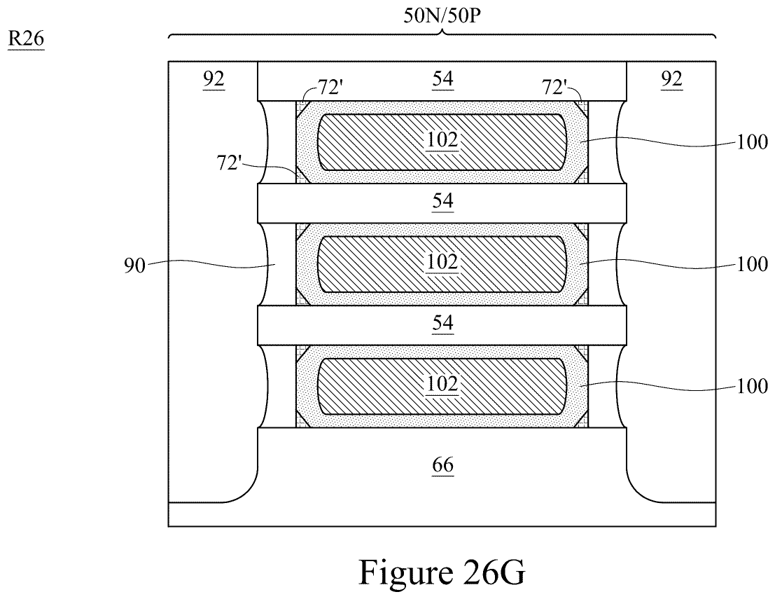

In FIGS. 26A-26G, replacement gates are formed by removing the sacrificial material 72, and forming gate dielectric layers and 100 gate electrodes 102 in place of the sacrificial material 72, similarly as described above in connection with FIGS. 17A-17F. As noted above, the gate electrodes 102 and the gate dielectric layers 100 may be collectively referred to as “gate structures.” After forming the replacement gate structures, additional processing steps are performed as described above in connection with FIGS. 18A-20C.

FIGS. 26C-26G illustrate exemplary views of region R26 of FIG. 26B, including the second nanostructures 54, the fins 66, the inner spacers 90, the epitaxial source/drain regions 92, the gate dielectric layers 100, and the gate electrode 102. In particular, the illustrated embodiments provide variations in profiles for the replacement gate features formed in the second recesses 98. FIGS. 26C-26F illustrate formation of the gate structures (e.g., the gate dielectric layers 100 and the gate electrode 102) as subsequent to the embodiments illustrated in FIGS. 24C-24F, respectively.

Note that, as illustrated by FIGS. 26D and 26G, the residue of the sacrificial material 72′ may remain on the inner spacers 90, such as between the inner spacers 90 and the gate dielectric layers 100. As discussed above, the sacrificial material residue 72′ may remain, and the gate dielectric layers 100 may be formed on the sacrificial material residue 72′. The sacrificial material residue 72′ is an insulating material (e.g., silicon oxide) and may have little to no impact on the electrical performance of the resulting device.

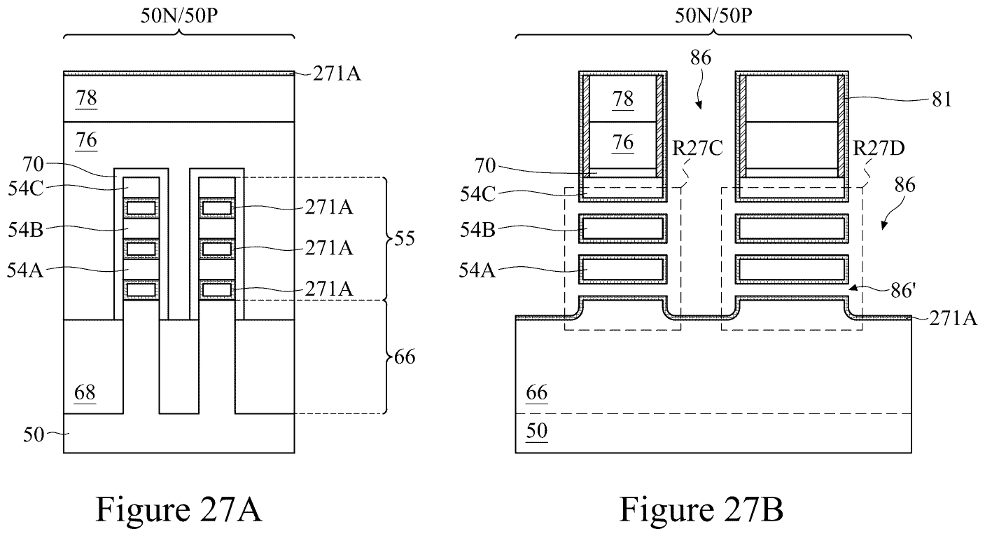

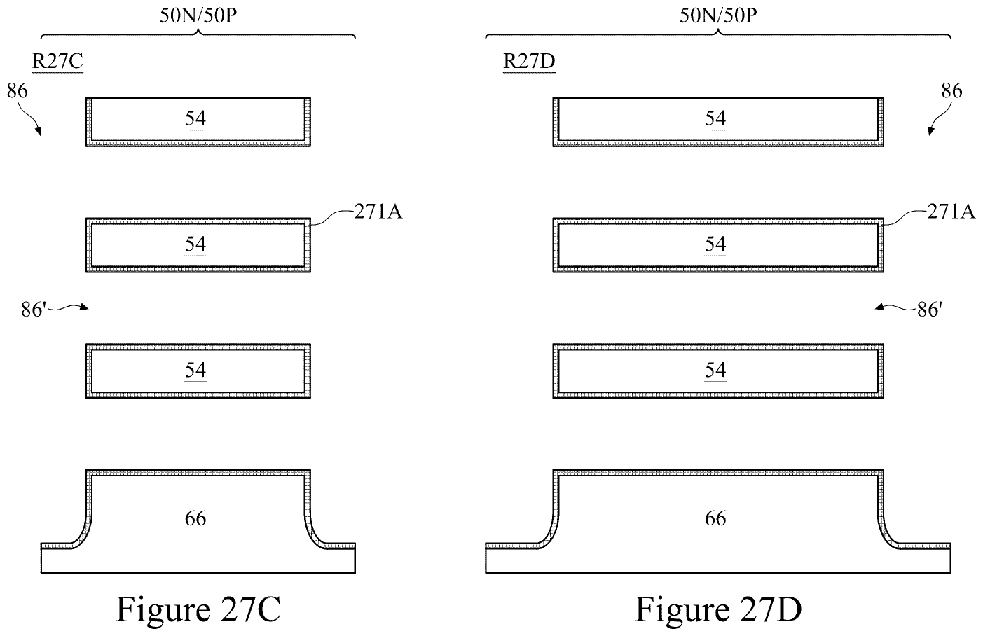

FIGS. 27A-33D illustrate embodiments for forming sacrificial material 272 after removal of the first nanostructures 52 as described above in connection with FIGS. 8A and 8B. For example, a multiple-deposition process may be used to form the combined material layer 271 (e.g., a first material layer 271A, a second material layer 271B, a third material layer 271C, a fourth material layer 272D, etc.). As discussed in greater detail below, the layers 271A/271B/271C/271D may be formed with improved control over widths of the sacrificial material 272 and, therefore, improved control over widths and profiles of subsequently formed inner spacers 90. In particular, these embodiments allow for the combined material layer 271 to be formed and etched into sacrificial material 272 for narrow and wide nano-FETs (e.g., short and long channel regions or gate widths, respectively) simultaneously. These embodiments allow for inner spacers 90 to be formed and shaped for the narrow and wide nano-FETs simultaneously as well. Although the combined material layer 271 is discussed herein with four deposition steps, any suitable number of deposition steps may be utilized in accordance with the discussion below. Some of the layers 271A/271B/271C/271D may be formed similarly as described in connection with analogous layers 71A/71B or layers 171A/171B/171C, unless otherwise specified below.

In accordance with various embodiments, formation of the sacrificial material 272 achieves similar advantages as described above in connection with the sacrificial material 72/172. In addition, formation of the sacrificial material 272 can be performed simultaneously or in parallel between narrow-channel and wide-channel nano-FETs. In particular, typical loading effects due to varying channel sizes may be prevented or reduced, such as forming inner spacers 90 with consistent dimensions. This consistency benefits subsequent processes while preventing channel damage, resistance at channel RCH, and spatial collection efficiency (SCE) loss for the nano-FETs (e.g., the wide-channel nano-FETs). In addition, the various advantages achieved by the sacrificial material 272 improves channel turn-on of the nano-FETs as well as other silicon channel electrical behaviors.

In FIGS. 27A-27D, a first material layer 271A is deposited over and around the second nanostructures 54 in the recesses 86 and gaps 86′ where the first nanostructures 52 were removed. The first material layer 271A may be deposited by a conformal deposition process, such as ALD, CVD (e.g., FCVD), or the like. The first material layer 271A may comprise an insulating material such as an oxide, including silicon oxide (e.g., SiOₓ such as SiO₂), silicon oxynitride, silicon oxycarbide, silicon oxycarbonitride, or the like, that can be selectively etched from the second nanostructures 54. In various embodiments, the first material layer 271A is free of germanium. For example, the first material layer 271A may be an oxide layer formed by ALD in order to be thin while providing full coverage around the second nanostructures 54.

FIGS. 27C and 27D illustrate exemplary views of regions R27C and R27D of FIG. 27B, respectively. FIG. 27C illustrates an intermediate step in the formation of a narrow-channel nano-FET, while FIG. 27D illustrates an intermediate step in the formation of a wide-channel nano-FET. Note that each of these embodiment nano-FETs may be located in the n-type region 50N and/or the p-type region 50P.

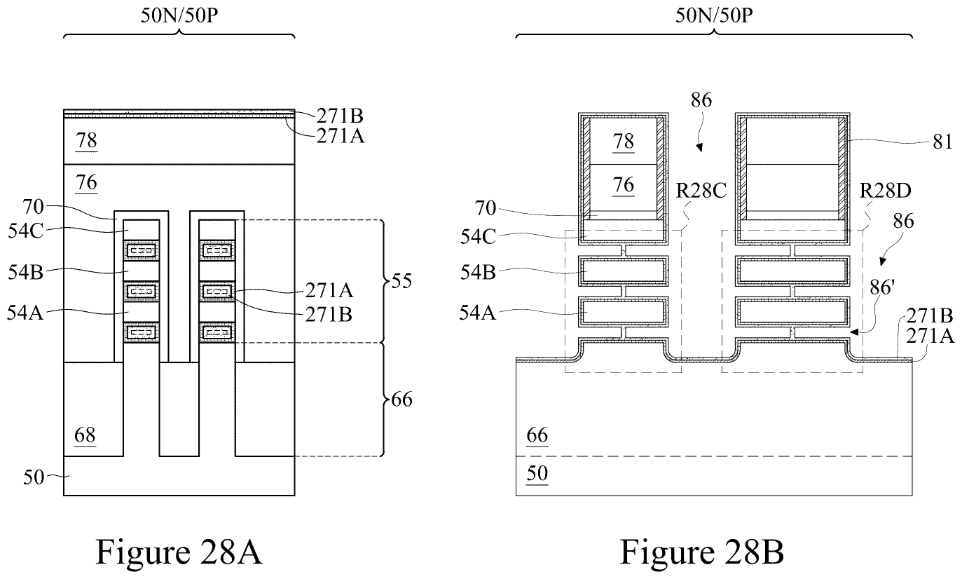

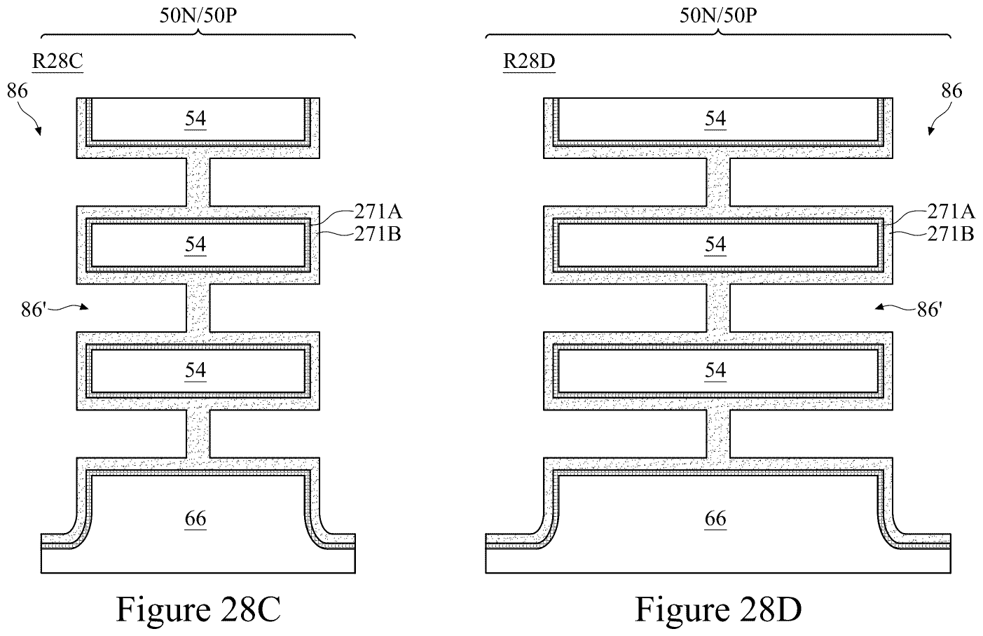

In FIGS. 28A-28D, a second material layer 271B is deposited over the first material layer 271A in the recesses 86 and gaps 86′ between the second nanostructures 54. The second material layer 271B may be deposited by a conformal process, such as CVD (e.g., FCVD), ALD, or the like. The second material layer 271B may comprise an insulating material such as silicon oxide (e.g., SiOₓ such as SiO₂), silicon germanium, silicon nitride, silicon oxycarbide, silicon oxycarbonitride, or the like that can be selectively etched from the second nanostructures 54.

In accordance with various embodiments, the second material layer 271B is formed through a first FCVD cycle. The first FCVD cycle may be performed by depositing a precursor that includes silicon, oxygen, hydrogen, and/or nitrogen. The precursor may include oligomers condensed over the first material layer 271A. After depositing the precursor, UV energy may be applied to polymerize (or further polymerize) the precursor (e.g., oligomers) in order to form the second material layer 271B. For example, the UV treatment may be performed at 50% to 90% of power at a wavelength ranging from 200 nm to 250 nm for a duration ranging from 40 seconds to 60 seconds. The second material layer 271B may be formed to a thickness ranging from 40 Å to 60 Å.

In some embodiments, the UV treatment is performed on one set of nano-FETs and not the other or at varying specifications within these ranges. For example, a stronger UV treatment may be performed on the narrow-channel nano-FETs than on the wide-channel nano-FETs. For example, the second material layer 271B on the narrow-channel nano-FETs may have a higher density, thereby ensuring the corresponding gaps 86′ between those second nanostructures 54 is filled during subsequent FCVD cycles at substantially the same time as those corresponding gaps 86′ in the wide-channel nano-FETs. In addition, the second material layer 271B on the narrow-channel nano-FETs may have a higher etch rate than the second sacrificial material 271B on the wide-channel nano-FETs during a subsequent etch process to form inner spacers.

FIGS. 28C and 28D illustrate exemplary views of regions R28C and R28D of FIG. 28B, respectively. FIG. 28C illustrates an intermediate step in the formation of a narrow-channel nano-FET, while FIG. 28D illustrates an intermediate step in the formation of a wide-channel nano-FET. In some embodiments, the second material layer 271B may merge with itself to form a wall within the gaps 86′ between the second nanostructures 54.

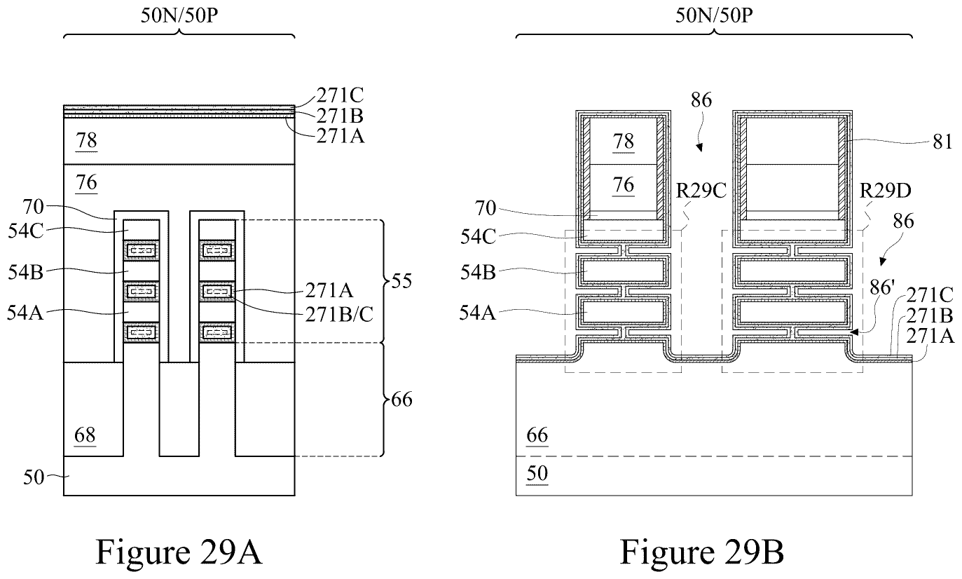

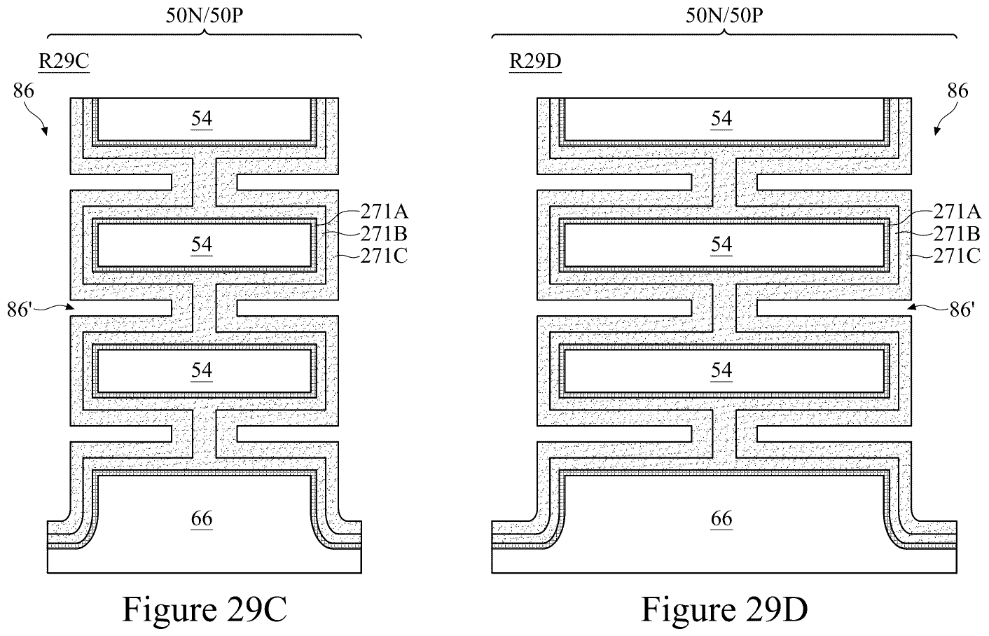

In FIGS. 29A-29D, a third material layer 271C is deposited over the second material layer 271B in the recesses 86 and gaps 86′ between the second nanostructures 54. The third material layer 271C may be deposited and treated similarly as the second material layer 271B (e.g., FCVD) and comprise the same insulating material (e.g., an oxide such as silicon oxycarbonitride). In accordance with various embodiments, the third material layer 271C is formed through a second FCVD cycle by depositing a precursor that includes silicon, oxygen, hydrogen, and/or nitrogen. The precursor may include oligomers condensed over the second material layer 271B. After depositing the precursor, UV energy may be applied to polymerize (or further polymerize) the precursor in order to form the third material layer 271C, similarly as described above in connection with the second material layer 271B. The third material layer 271C may be formed to a thickness ranging from 40 Å to 60 Å.

It should be appreciated that the material layers 271A/271B may be formed with distinct and particular properties. For example, controlling the deposition thicknesses and/or the UV exposure time may affect the densities and/or etch rates of the material layers 271A/271B. As a result, benefits may be achieved relating to subsequent processing, such as controlled etching to form the notches 87, formation of the inner spacers 90, etc.

FIGS. 29C and 29D illustrate exemplary views of regions R29C and R29D of FIG. 29B, respectively. FIG. 29C illustrates an intermediate step in the formation of a narrow-channel nano-FET, while FIG. 29D illustrates an intermediate step in the formation of a wide-channel nano-FET. As illustrated, the third material layer 271C may continue to form over and widen the wall of the second material layer 271B within the gaps 86′ between the second nanostructures 54. It should be appreciated that the material layers 271A/271B/271C are thus far filling the gaps 86′ based on their thicknesses more than by the widening wall. This is a benefit that applies to the narrow-channel and wide-channel nano-FETs alike to ensure that the gaps 86′ for each will be filled at substantially the same time (e.g., during the same FCVD cycle).

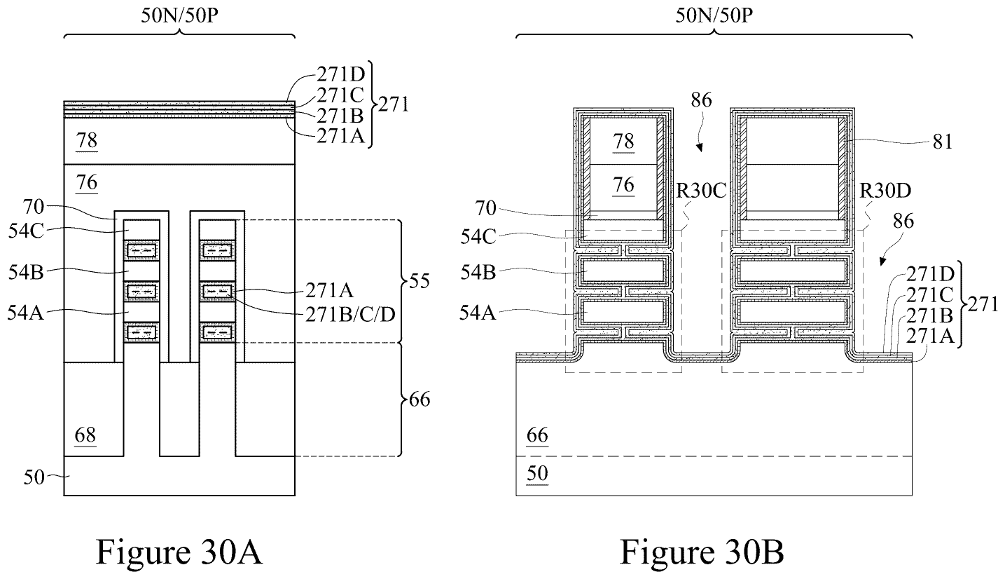

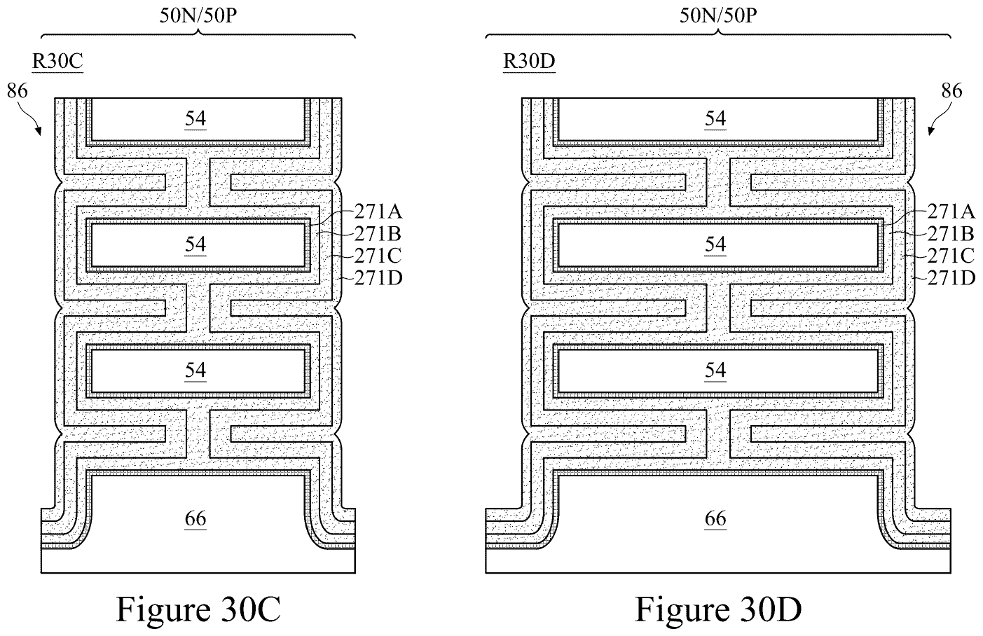

In FIGS. 30A-30D, a fourth material layer 271D is deposited over the third material layer 271C in the recesses 86 and gaps 86′ between the second nanostructures 54. The fourth material layer 271D represents the material layer which fills a remainder of the gaps 86′ between the second nanostructures 54. In some embodiments (not specifically illustrated), other material layers may be deposited and treated similarly as described for the second material layer 271B and the third material layer 271C before forming the fourth material layer 271D to fill the remainder of the gaps 86′ for both types of nano-FETs. As illustrated, the resulting combined material layer 271 (e.g., the first material layer 271A, the second material layer 271B, the third material layer 271C, and the fourth material layer 271D) may comprise multi-layer portions between the second nanostructures 54. In some embodiments, the individual layers of the combined material layer 271 may not be easily distinguishable from one another.

In accordance with various embodiments, the fourth material layer 271D is formed through a third FCVD cycle (or an N^{th} FCVD cycle if additional material layers were formed). The fourth material layer 271D may be formed using precursors that include silicon, oxygen, hydrogen, and/or nitrogen. After depositing the fourth material layer 271D, a high temperature treatment may be performed instead of a UV treatment. For example, the high temperature treatment may include an SPM mixture (e.g., a sulfuric peroxide mixture comprising sulfuric acid, hydrogen peroxide, and water). During the high temperature treatment, oxygen may replace other elements such as carbon and/or nitrogen. As a result, an oxygen atomic concentration may increase, while a carbon atomic concentration and/or a nitrogen atomic concentration decrease. In some embodiments, the fourth material layer 271D may be converted to silicon oxide. In some cases, outward sidewalls of the fourth material layer 271D (e.g., exterior to the now-filled gaps 86′) are converted to silicon oxide, while some portions of the fourth material layer 271D interposed between the second nanostructures 54 may experience only a partial conversion.

FIGS. 30C and 30D illustrate exemplary views of regions R30C and R30D of FIG. 30B, respectively. FIG. 30C illustrates an intermediate step in the formation of a narrow-channel nano-FET, while FIG. 30D illustrates an intermediate step in the formation of a wide-channel nano-FET. As illustrated, the fourth material layer 271D may continue to form over the wall of the previous material layers 271B/271C within the gaps 86′ between the second nanostructures 54. However, notably, the fourth material layer 271D fills remainders of the gaps 86′ before the widening wall could reach the sidewalls of the second nanostructures 54. As a result, the gaps 86′ of the narrow-channel and wide-channel nano-FETs alike are filled at substantially the same time (e.g., during the third FCVD cycle). Moreover, the combined material layer 271 may have a thickness along sidewalls of the second nanostructures 54 ranging from o nm to 4 nm for both the narrow-channel and the wide-channel nano-FETs alike. In some embodiments, both instances of the combined material layer 271 may have similar outward sidewall profiles, such as including indentions laterally adjacent to the now-filled gaps 86′.

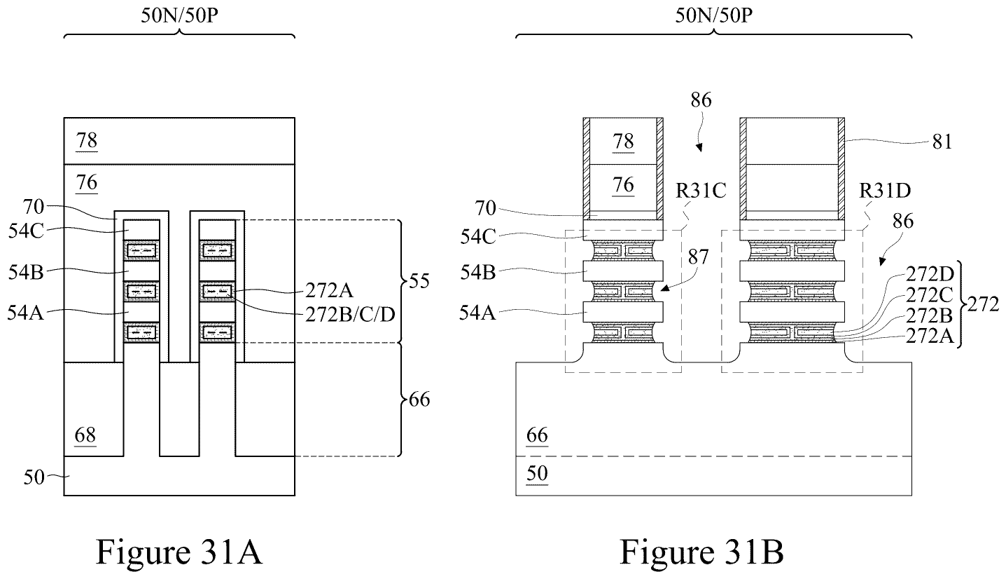

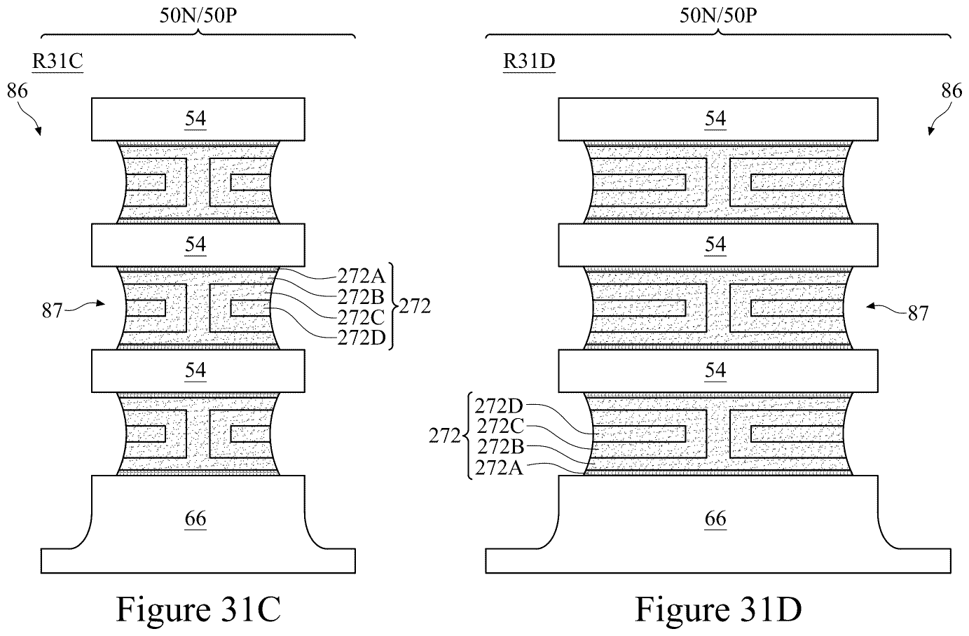

In FIGS. 31A-31D, the combined material layer 271 (e.g., the first material layer 271A, the second material layer 271B, the third material layer 271C, and the fourth material layer 271D) may then be etched to form sacrificial material 272 (e.g., comprising first sacrificial material segments 272A, second sacrificial material segments 272B, third sacrificial material segments 272C, a fourth sacrificial material layer 272D). The etching may be isotropic or anisotropic. For example, the combined material layer 271 may be etched by a wet etch process using diluted HF, or the like as an etchant. In some embodiments, the etching is performed to form notches 87 (e.g., recesses) in sidewalls of the sacrificial material 272 from sidewalls of the second nanostructures 54. Similarly as with the previous embodiments, the notches 87 may be concave, convex, or straight.

FIGS. 31C and 31D illustrate exemplary views of regions R31C and R31D of FIG. 31B, respectively. FIG. 31C illustrates an intermediate step in the formation of a narrow-channel nano-FET, while FIG. 31D illustrates an intermediate step in the formation of a wide-channel nano-FET. As illustrated, the notches 87 in the sacrificial material 272 for both types of nano-FETs may have similar or substantially same depths. Although sidewalls of the sacrificial material 272 are illustrated as being concave, the sacrificial material 272 may have other profiles (e.g., convex or straight) as described above in previous embodiments.

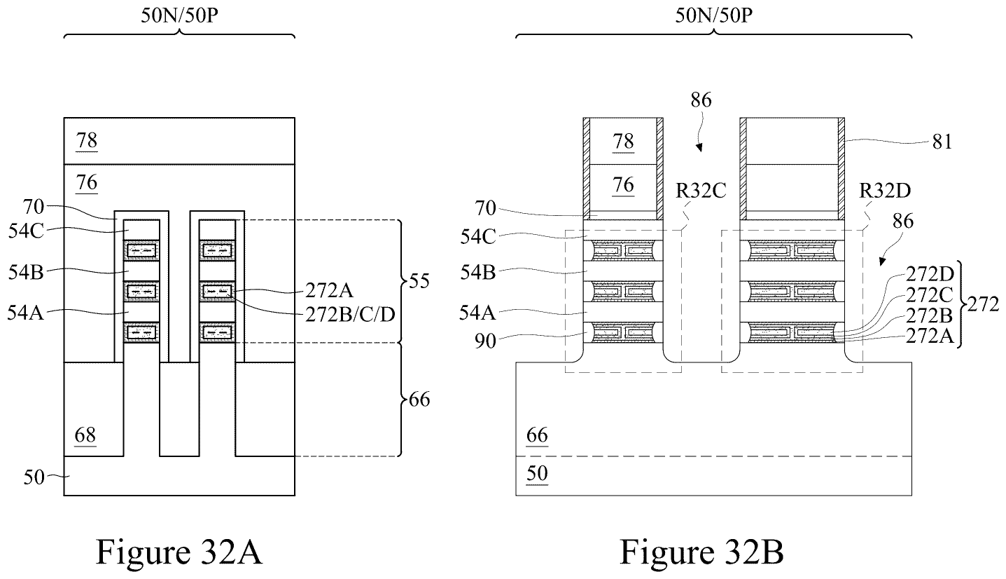

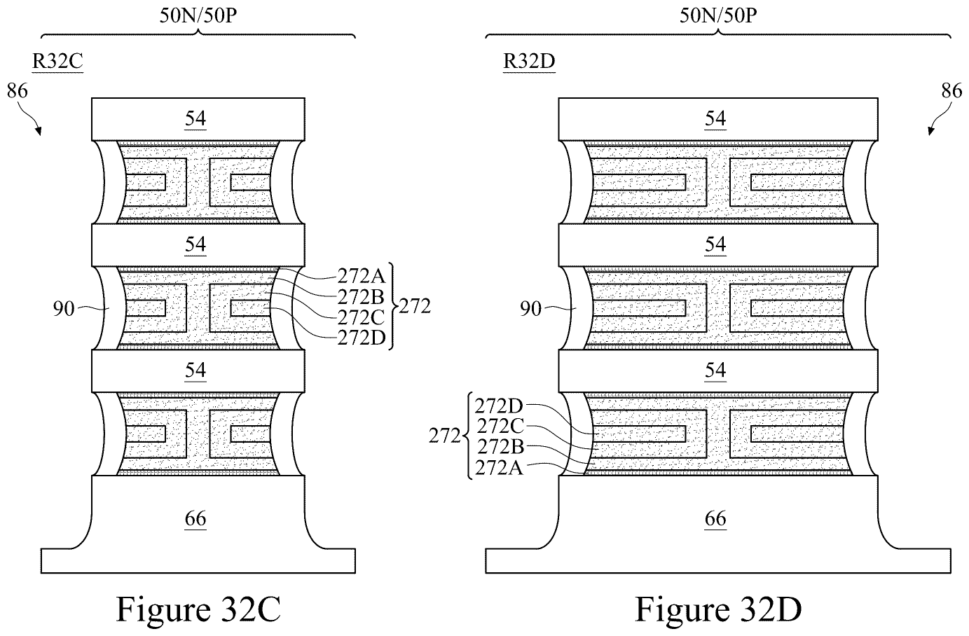

In FIGS. 32A-32D, inner spacers 90 are formed in the notches 87 adjacent to the sacrificial material 72, similarly as described above. The inner spacers 90 act as isolation features between subsequently formed source/drain regions and a subsequently formed gate structure. The inner spacers 90 may be formed by depositing an inner spacer layer (not separately illustrated) over the structures illustrated in FIGS. 31A-31D. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 90. The inner spacer layer may be etched by an anisotropic etching process, such as RIE, NBE, or the like.

FIGS. 32C and 32D illustrate exemplary views of regions R32C and R32D of FIG. 32B, respectively. FIG. 32C illustrates an intermediate step in the formation of a narrow-channel nano-FET, while FIG. 32D illustrates an intermediate step in the formation of a wide-channel nano-FET. As illustrated, widths of the inner spacers 90 for both types of nano-FETs may be similar or substantially the same. Although outward sidewalls of the inner spacers 90 are illustrated as straight and flush in FIG. 32B, the outward sidewalls may have other profiles such as concave and recessed as illustrated in FIGS. 32C and 32D.

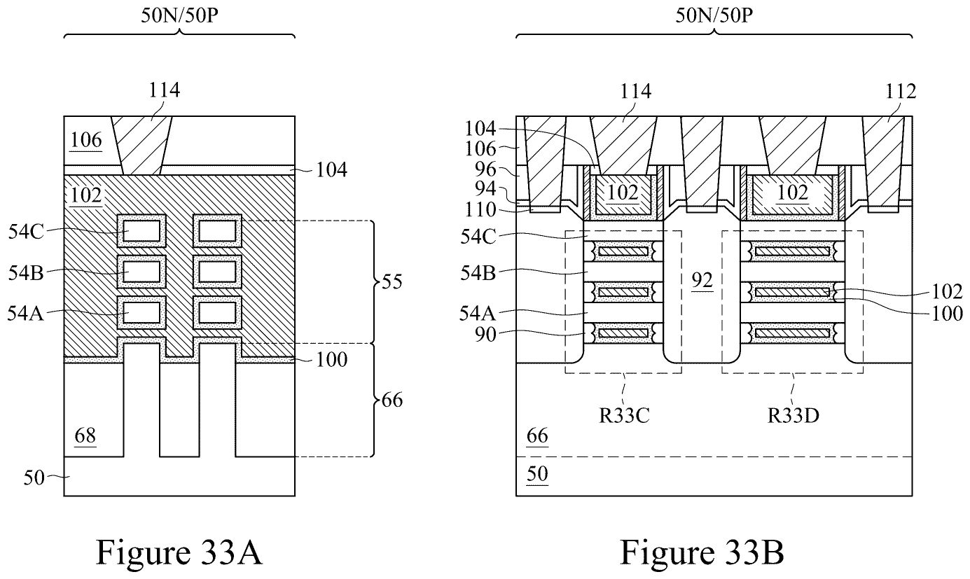

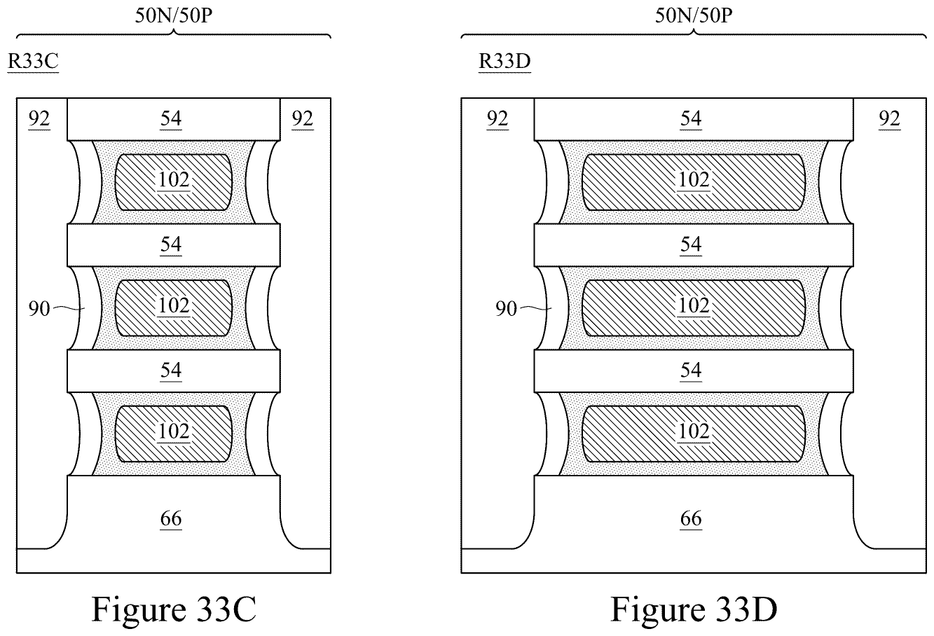

In FIGS. 33A-33D, replacement gates are formed by removing the sacrificial material 72, and forming gate dielectric layers 100 and gate electrodes 102 in place of the sacrificial material 72, similarly as described above in connection with FIGS. 17A-17F. As noted above, the gate electrodes 102 and the gate dielectric layers 100 may be collectively referred to as “gate structures.” After forming the replacement gates, additional processing steps are performed as described above in connection with FIGS. 18A-20C.

FIGS. 33C and 33D illustrate exemplary views of regions R33C and R33D of FIG. 33B, respectively. FIG. 33C illustrates an intermediate step in the formation of a narrow-channel nano-FET, while FIG. 33D illustrates an intermediate step in the formation of a wide-channel nano-FET. As illustrated, the gate structures for both types of nano-FETs will have substantially the same dimensions between the second nanostructures 54 as the respective sacrificial materials 272 before removal.

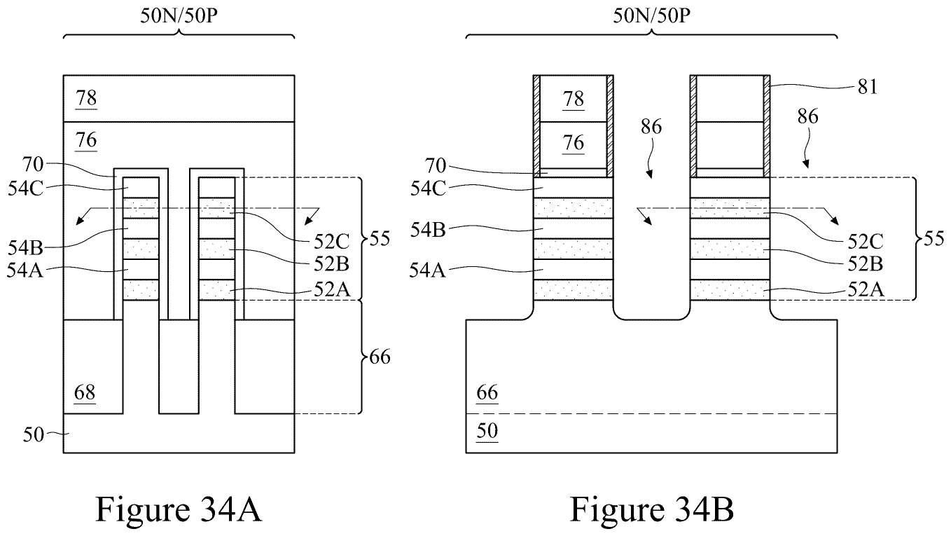

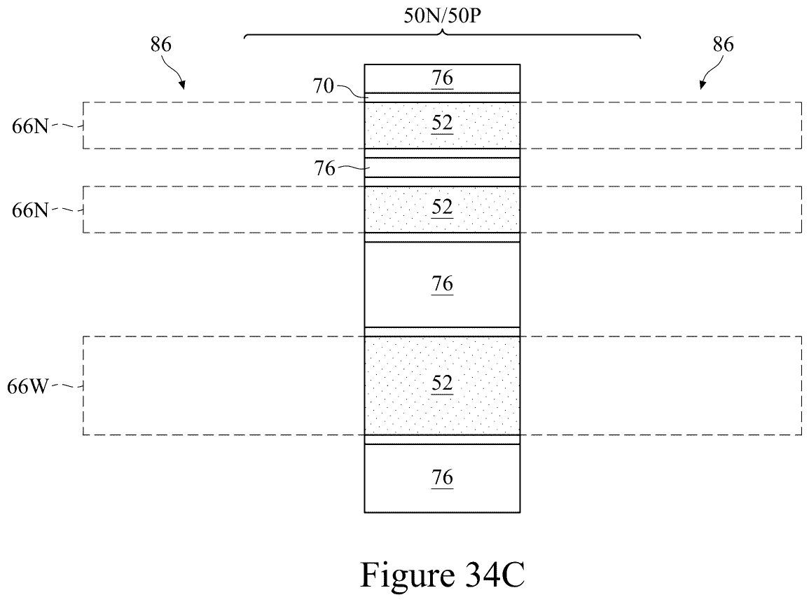

FIGS. 34A-38C illustrate embodiments in which a combination of the above described embodiments are selected for forming sacrificial material 372 after removal of the first nanostructures 52 as described above in connection with FIGS. 8A and 8B. For example, a first embodiment may be selected for a first set of nano-FETs, and a second embodiment may be selected for a second set of nano-FETs. In some embodiments, the first set of nano-FETs may include narrow fins 66N, while the second set of nano-FETs may include wide fins 66W. The first and second embodiments may be selected so that some or all of the respective steps of depositing the material layers 371A/371B/etc., etching the combined material layers 371 to form the sacrificial material 372, forming the inner spacers 90, and removing the sacrificial material 372 may be performed simultaneously. In particular, the first and second embodiments may be selected in order for the steps relating to formation of the inner spacers 90 can be performed simultaneously while also forming the respective inner spacers 90 with critical dimensions that are appropriate for each of the first set of nano-FETs (e.g., narrow fins 66N) and the second set of nano-FETs (e.g., wide fins 66W).

In accordance with various embodiments, formation of the sacrificial material 372 achieves similar advantages as described above in connection with the sacrificial material 72/172/272. In addition, formation of the sacrificial material 372 can be performed simultaneously or in parallel between narrow-fin and wide-fin nano-FETs. In particular, typical loading effects due to varying fin sizes may be prevented or reduced, such as forming inner spacers 90 with consistent dimensions. This consistency benefits subsequent processes while preventing channel damage, resistance at channel RCH, and spatial collection efficiency (SCE) loss for the nano-FETs (e.g., the wide-channel nano-FETs). In addition, the various advantages achieved by the sacrificial material 272 improves channel turn-on of the nano-FETs as well as other silicon channel electrical behaviors.

In FIGS. 34A-34C, a structure corresponding to FIGS. 7A and 7B is provided, wherein FIG. 34C illustrates a top-down cross-sectional view as indicated by the dotted lines provided in FIGS. 34A and 34B. (Note that the subsequent figures follow this same pattern.) Although labeling of the figures implies that FIG. 34A illustrates the narrow-fin nano-FETs, FIG. 34A may analogously apply to the wide-fin nano-FETs. In addition, FIG. 34B may similarly represent both the narrow-fin nano-FETs and the wide-fin nano-FETs.

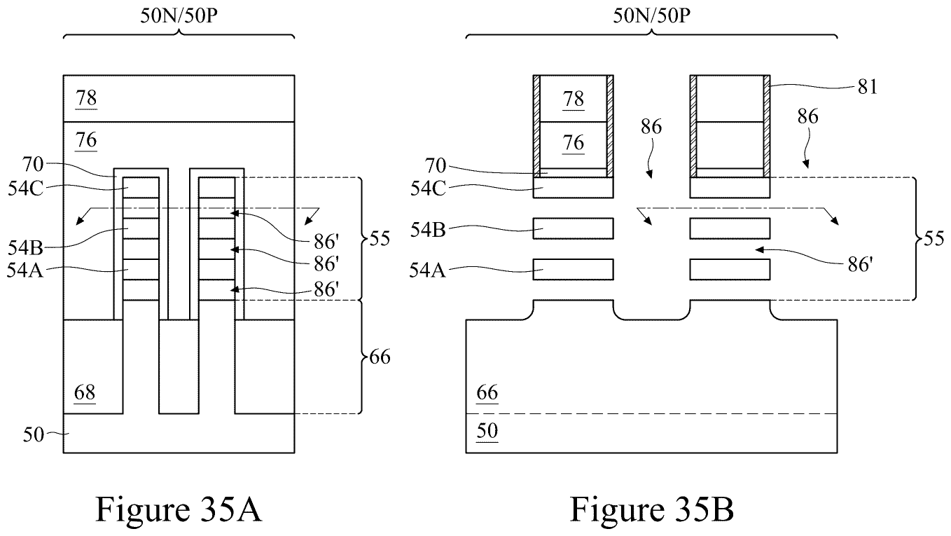

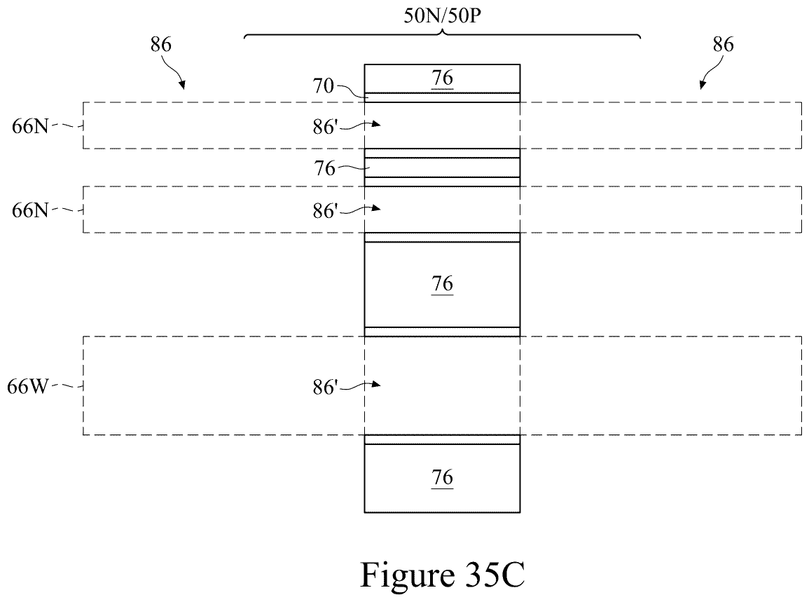

In FIGS. 35A-35C, the first nanostructures 52 are removed to extend recesses 86 between the second nanostructures 54, similarly as described above in connection with FIGS. 8A and 8B. As illustrated, the recesses 86 are extended to include gaps 86′ between the second nanostructures 54.

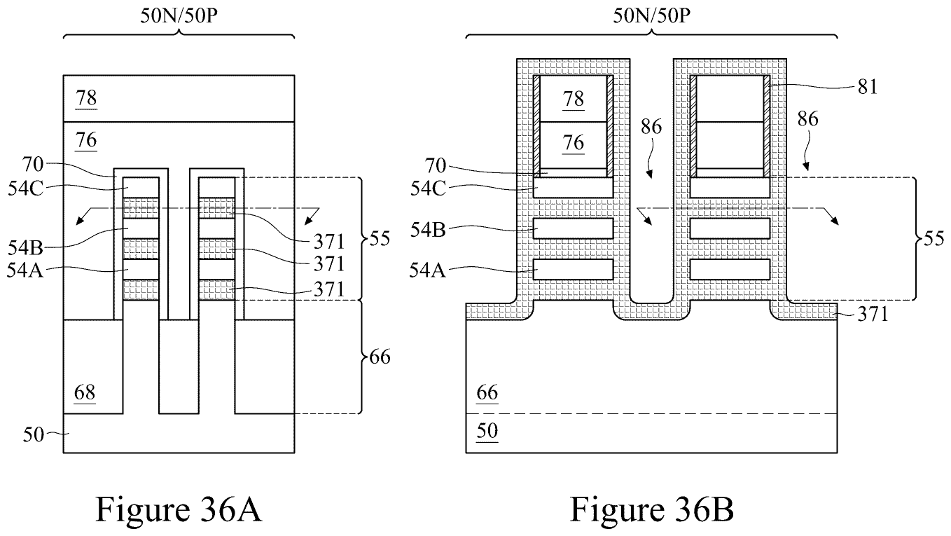

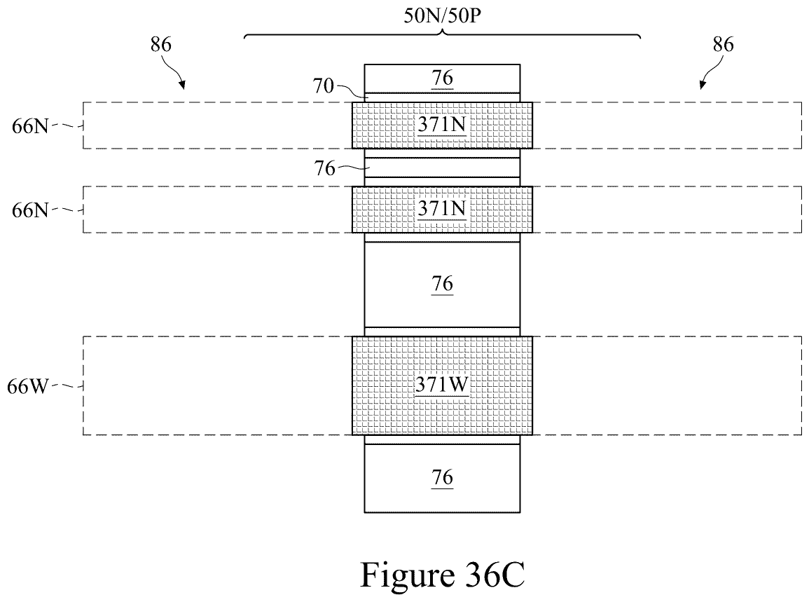

In FIGS. 36A-36C, a narrow-fin material layer 371N and a wide-fin material layer 371W are formed in the recesses 86 and gaps 86′ between the second nanostructures 54, similarly as described above in relevant embodiments. For example, each of the material layers 371N/371W may be formed as described in connection with FIGS. 9A-10B, 21A-23B, or 27A-30D. As noted above, the material layers 371N/371W may be formed of different materials and/or using different processes. In some embodiments, the material layers 371N/371W are formed simultaneously or in parallel (e.g., some steps simultaneously and some steps separately) and may, in some cases, be a continuous material layer 371.

Optionally, after formation, either or both of the material layers 371N/371W may receive treatments which change their etch selectivities with respect to one another. For example, follow formation of the material layers 371N/371W, the narrow-fin material layer 371N may have a greater etch rate than the wide-fin material layer 371W. This distinction in etch selectivities may compensate for an etching phenomenon (e.g., a loading effect) in which etching a sacrificial material in the first set of nano-FETs (e.g., narrow fins 66N) may be slower than etching a same sacrificial material in the second set of nano-FETs (e.g., wide fins 66W).

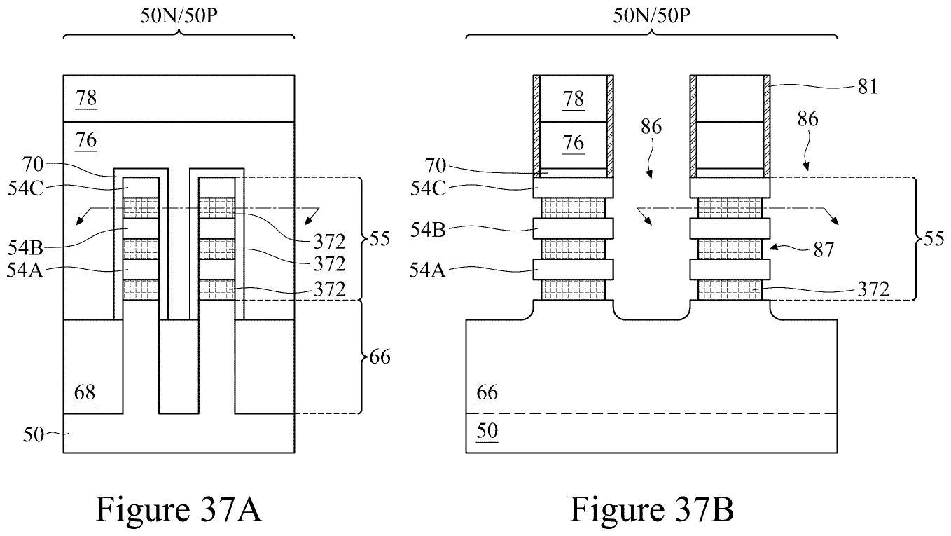

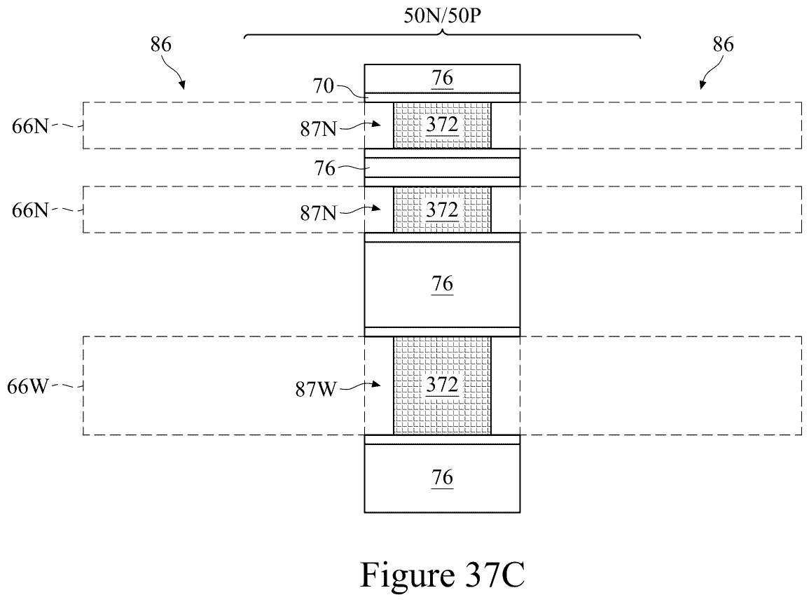

In FIGS. 37A-37C, the narrow-fin material layer 371N and the wide-fin material layer 371W may then be etched to form a narrow-fin sacrificial material 372N and a wide-fin sacrificial material 372W, respectively. The etching may be isotropic or anisotropic. For example, the material layers 371N/371W may be etched by a wet etch process using diluted HF, or the like as an etchant. In some embodiments, the etching is performed to form notches 87N/87W (e.g., recesses) in sidewalls of the sacrificial materials 372N/372W from sidewalls of the second nanostructures 54. Similarly as with the previous embodiments, the corresponding notches 87 of the narrow-fin nano-FETs and the wide-fin nano-FETs may be concave, convex, or straight. In particular, the respective notches 87 may the profiles associated with the selected embodiments. In accordance with various embodiments, the notches 87N may have a similar shape and same depth as the notches 87W because the selection of embodiments for forming the sacrificial materials 371 is able to reduce loading effects associated with the different sizes of the fins 66N/66W.

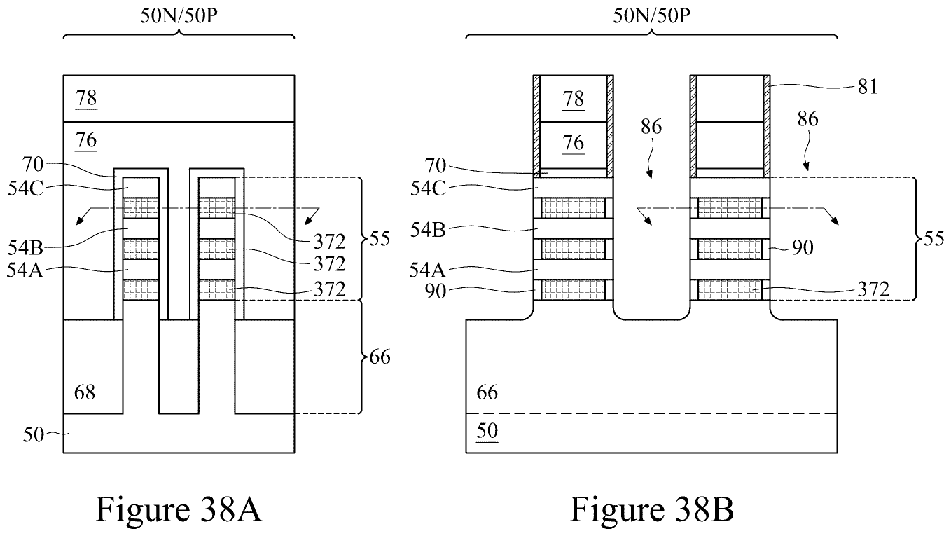

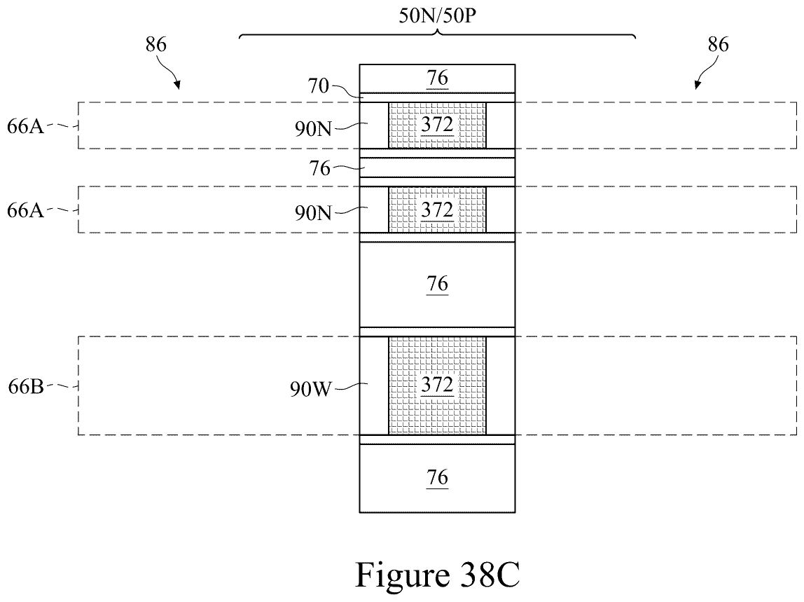

In FIGS. 38A-38C, inner spacers 90N/90W are formed in the recesses adjacent to the sacrificial material 372N/372W, similarly as described above in connection with FIGS. 12A-12H, 25A-25B, and 32A-32D. Although illustrated as straight and flush with the second nanostructures 54, the inner spacers 90 may be concave or convex as well as recessed from the second nanostructures 54. In various embodiments, the inner spacers 90N may have a similar shape and same depth as the inner spacers 90W due to the above discussed reduction in loading effects during formation of the notches 87N/87W. As discussed previously, similar benefits are achieved for the subsequent processing steps.

Although not specifically illustrated, further processing steps may be performed as discussed above to continue formation of the first set of nano-FETs and the second set of nano-FETs. For example, subsequent processing may be performed on the narrow-fin and wide-fin nano-FETs, similarly as described above in connection with FIGS. 13A-20C.

Embodiments achieve various advantages. In particular, the disclosed embodiments form nano-FETs by replacing the first nanostructures 52 with sacrificial material 72/172/272/372, and forming notches 87 in the sacrificial material 72/172/272/372 which improve control and yield for subsequent processing steps. In particular, the inner spacers 90 may be formed within the notches 87 with desired shapes and dimensions, the replacement gate structures may be formed with sidewalls that follow the profiles of the inward sidewalls of the inner spacers 90, and these various processing steps may be performed with reduced damage to the second nanostructures, greater stress modulation, and reduced loading effects. As a result, the nano-FETs may be fabricated at a higher yield and with improved performance and reliability.

In an embodiment, a method includes forming a first semiconductor layer over a substrate; forming a second semiconductor layer over the first semiconductor layer; performing a first etch process on the first semiconductor layer and the second semiconductor layer to form a first fin; forming a gate structure across the first fin; performing a second etch process to form a first recess and a second recess in the first fin; removing the first semiconductor layer; depositing a first material layer along exposed surfaces of the second semiconductor layer and the substrate; depositing a second material layer over the first material layer; etching the first material layer and the second material layer to form a third recess from first sidewalls of the second semiconductor layer and the substrate at the first recess, a first etch rate of the first material layer being different than a second etch rate of the second material layer; forming an inner spacer in the third recess; and forming a source/drain region in the first recess. In another embodiment, removing the first semiconductor layer comprises connecting the first recess to the second recess between the second semiconductor layer and the substrate. In another embodiment, etching the first material layer and the second material layer comprises forming a fourth recess from second sidewalls of the second semiconductor layer and the substrate at the second recess. In another embodiment, the second etch rate is greater than the first etch rate, and wherein outward sidewalls of the first material layer and the second material layer have a concave shape. In another embodiment, the first etch rate is greater than the second etch rate, and wherein outward sidewalls of the first material layer and the second material layer have a convex shape. In another embodiment, both of the first material layer and the second material layer comprise a same material, and wherein depositing the first material layer and depositing the second material layer comprise different processes. In another embodiment, the first material layer and the second material layer comprise different materials. In another embodiment, the inner spacer has a first lateral width extending from the first material layer to the source/drain region, wherein the inner spacer has a second lateral width extending from the second material layer to the source/drain region, and wherein the first lateral width is different than the second lateral width. In another embodiment, the second lateral width is greater than the first lateral width.

In an embodiment, a method includes forming a stack of alternating first epitaxy layers and second epitaxy layers over a substrate; patterning the stack to form a semiconductor fin over the substrate; forming a gate structure over the semiconductor fin; recessing the semiconductor fin to form a source/drain recess adjacent to the gate structure; removing the first epitaxy layers to form gaps between the second epitaxy layers; forming a first material layer over and around the second epitaxy layers; forming a second material layer over and around the first material layer; forming a third material layer over and around the second material layer, the third material layer filling a remainder of the gaps; etching sidewalls of the first material layer, the second material layer, and the third material layer to form notches in the sidewalls, the first material layer and the second material layer having different etch rates; and forming inner spacers in the notches. In another embodiment, forming the first material layer comprises performing a first atomic layer deposition process, wherein forming the second material layer comprises performing a second atomic layer deposition process, and wherein the first material layer and the second material layer comprise different materials. In another embodiment, forming the third material layer comprises performing a flowable chemical vapor deposition process. In another embodiment, the second material layer has a greater etch rate than the first material layer and the third material layer. In another embodiment, the notches have a W-shaped profile.

In an embodiment, a method includes alternately stacking first epitaxy layers and second epitaxy layers to form a semiconductor stack over a substrate; patterning the semiconductor stack to form a fin; forming a gate structure over the fin; recessing the fin on opposite sides of the gate structure; removing the first epitaxy layers from the fin to form gaps between the second epitaxy layers; forming a combined material layer over the second epitaxy layers and in the gaps, forming the combined material layer comprising: performing an atomic layer deposition to form a first material layer over the second epitaxy layers; performing a first flowable chemical vapor deposition to form a second material layer over the first material layer; performing a second flowable chemical vapor deposition to form a third material layer over the second material layer; etching the combined material layer to form notches extending inward from sidewalls of the second epitaxy layers; and forming inner spacers in the notches. In another embodiment, performing the first flowable chemical vapor deposition comprises: applying a first precursor over the first material layer; and applying UV energy to the first precursor to form the second material layer. In another embodiment, performing the second flowable chemical vapor deposition comprises: applying a second precursor over the second material layer; and applying UV energy to the second precursor to form the third material layer. In another embodiment, the first precursor and the second precursor are the same. In another embodiment, forming the combined material layer further comprises: performing additional flowable chemical vapor depositions to form additional material layers until the gaps are filled; and between each one of the additional flowable chemical vapor depositions, applying UV energy to a newest layer of the additional material layers. In another embodiment, the method further includes performing a high temperature sulfuric peroxide treatment on the combined material layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first semiconductor layer over a substrate;
forming a second semiconductor layer over the first semiconductor layer;
performing a first etch process on the first semiconductor layer and the second semiconductor layer to form a first fin;
forming a gate structure across the first fin;
performing a second etch process to form a first recess and a second recess in the first fin;
removing the first semiconductor layer;
depositing a first material layer along exposed surfaces of the second semiconductor layer and the substrate;
depositing a second material layer over the first material layer;
etching the first material layer and the second material layer to form a third recess from first sidewalls of the second semiconductor layer and the substrate at the first recess, a first etch rate of the first material layer being different than a second etch rate of the second material layer;
forming an inner spacer in the third recess; and
forming a source/drain region in the first recess.

2. The method of claim 1, wherein removing the first semiconductor layer comprises connecting the first recess to the second recess between the second semiconductor layer and the substrate.

3. The method of claim 1, wherein etching the first material layer and the second material layer comprises forming a fourth recess from second sidewalls of the second semiconductor layer and the substrate at the second recess.

4. The method of claim 1, wherein the second etch rate is greater than the first etch rate, and wherein outward sidewalls of the first material layer and the second material layer have a concave shape.

5. The method of claim 1, wherein the first etch rate is greater than the second etch rate, and wherein outward sidewalls of the first material layer and the second material layer have a convex shape.

6. The method of claim 1, wherein both of the first material layer and the second material layer comprise a same material, and wherein depositing the first material layer and depositing the second material layer comprise different processes.

7. The method of claim 1, wherein the first material layer and the second material layer comprise different materials.

8. The method of claim 1, wherein the inner spacer has a first lateral width extending from the first material layer to the source/drain region, wherein the inner spacer has a second lateral width extending from the second material layer to the source/drain region, and wherein the first lateral width is different than the second lateral width.

9. The method of claim 8, wherein the second lateral width is greater than the first lateral width.

10. A method, comprising:
forming a stack of alternating first epitaxy layers and second epitaxy layers over a substrate;
patterning the stack to form a semiconductor fin over the substrate;
forming a gate structure over the semiconductor fin;
recessing the semiconductor fin to form a source/drain recess adjacent to the gate structure;
removing the first epitaxy layers to form gaps between the second epitaxy layers;
forming a first material layer over and around the second epitaxy layers;
forming a second material layer over and around the first material layer;
forming a third material layer over and around the second material layer, the third material layer filling a remainder of the gaps;
etching sidewalls of the first material layer, the second material layer, and the third material layer to form notches in the sidewalls, the first material layer and the second material layer having different etch rates; and
forming inner spacers in the notches.

11. The method of claim 10, wherein forming the first material layer comprises performing a first atomic layer deposition process, wherein forming the second material layer comprises performing a second atomic layer deposition process, and wherein the first material layer and the second material layer comprise different materials.

12. The method of claim 11, wherein forming the third material layer comprises performing a flowable chemical vapor deposition process.

13. The method of claim 10, wherein the second material layer has a greater etch rate than the first material layer and the third material layer.

14. The method of claim 13, wherein the notches have a W-shaped profile.

15. A method, comprising:
alternately stacking first epitaxy layers and second epitaxy layers to form a semiconductor stack over a substrate;
patterning the semiconductor stack to form a fin;
forming a gate structure over the fin;
recessing the fin on opposite sides of the gate structure;
removing the first epitaxy layers from the fin to form gaps between the second epitaxy layers;
forming a combined material layer over the second epitaxy layers and in the gaps, forming the combined material layer comprising:
performing an atomic layer deposition to form a first material layer over the second epitaxy layers;
performing a first flowable chemical vapor deposition to form a second material layer over the first material layer;
performing a second flowable chemical vapor deposition to form a third material layer over the second material layer;
etching the combined material layer to form notches extending inward from sidewalls of the second epitaxy layers; and
forming inner spacers in the notches.

16. The method of claim 15, wherein performing the first flowable chemical vapor deposition comprises:
applying a first precursor over the first material layer; and
applying UV energy to the first precursor to form the second material layer.

17. The method of claim 16, wherein performing the second flowable chemical vapor deposition comprises:
applying a second precursor over the second material layer; and
applying UV energy to the second precursor to form the third material layer.

18. The method of claim 17, wherein the first precursor and the second precursor are the same.

19. The method of claim 15, wherein forming the combined material layer further comprises:
performing additional flowable chemical vapor depositions to form additional material layers until the gaps are filled; and
between each one of the additional flowable chemical vapor depositions, applying UV energy to a newest layer of the additional material layers.

20. The method of claim 19, further comprising performing a high temperature sulfuric peroxide treatment on the combined material layer.
